(19) United States
(12) Patent Application Publication
(10) Pub. No.: US 2025/0248227 A1
(43) Pub. Date: Jul. 31, 2025

(54) DISPLAY PANEL AND METHOD OF MANUFACTURING THE SAME

(71) Applicant: Samsung Display Co., Ltd., Yongin-si (KR)

(72) Inventors: JOONYONG PARK, Yongin-si (KR); SUKYOUNG YANG, Yongin-si (KR); DONGMIN LEE, Yongin-si (KR); JONGHEE PARK, Yongin-si (KR)

(21) Appl. No.: 18/938,736

(22) Filed: Nov. 6, 2024

(30) Foreign Application Priority Data
Jan. 30, 2024 (KR) 10-2024-0014262

(51) Int. Cl. H10K 59/122; H10K 59/12; H10K 59/80; H10K 71/00; H10K 71/10; H10K 71/40; H10K 71/60; H10K 102/20

(52) U.S. Cl. CPC H10K 59/122; H10K 59/1201; H10K 59/80517; H10K 71/191; H10K 71/40; H10K 71/60; H10K 71/621; H10K 2102/20

(57) ABSTRACT

A display panel includes: an anode; a sacrificial pattern disposed on the anode and provided with a sacrificial opening to expose a portion of an upper surface of the anode; a pixel definition layer covering at least a portion of the sacrificial pattern and provided with a light emitting opening overlapping the sacrificial opening; a barrier wall disposed on the pixel definition layer and provided with a barrier wall opening overlapping the light emitting opening; a light emitting pattern disposed in the barrier wall opening, and a cathode being in contact with the barrier wall. The sacrificial pattern includes a metal oxide including tin, indium, and zinc, a tin content relative to a total content of tin, indium, and zinc contained in the sacrificial pattern is equal to or greater than about 18 at % and equal to or smaller than about 23 at %.

This application claims priority to Korean Patent Application No. 10-2024-0014262, filed on Jan. 30, 2024, and all the benefits accruing therefrom under 35 U.S.C. § 119, the content of which in its entirety is herein incorporated by reference.

### BACKGROUND

### 1. Field

The present disclosure relates to a display panel and a method of manufacturing the same. More particularly, the present disclosure relates to a display panel with improved display quality and a method of manufacturing the display panel.

### 2. Description of Related Art

Display devices providing images to a user, such as televisions, monitors, smartphones, and tablet computers, include a display panel to display the images. Various display panels, such as a liquid crystal display panel, an organic light emitting display panel, an electrowetting display panel, and an electrophoretic display panel, are being developed as the display panel.

The organic light emitting display panel includes an anode, a cathode, and a light emitting pattern. The light emitting pattern is provided in each light emitting area, and the cathode provides a common voltage to each light emitting area.

### SUMMARY

The present disclosure provides a display panel with improved process reliability when a light emitting element of the display panel is formed without using a metal mask.

The present disclosure provides a method of manufacturing the display panel.

Embodiments of the invention provide a display panel including: a base layer; an anode disposed on the base layer; a sacrificial pattern disposed on the anode and provided with a sacrificial opening to expose a portion of an upper surface of the anode; a pixel definition layer disposed on the base layer to cover at least a portion of the sacrificial pattern and provided with a light emitting opening overlapping the sacrificial opening; a barrier wall disposed on the pixel definition layer and provided with a barrier wall opening overlapping the light emitting opening; a light emitting pattern disposed on the anode and disposed in the barrier wall opening; and a cathode disposed on the light emitting pattern and being in contact with the barrier wall. The sacrificial pattern includes a metal oxide including tin (Sn), indium (In), and zinc (Zn), a tin content relative to a total content of tin, indium, and zinc contained in the sacrificial pattern is equal to or greater than about 18 atomic percent (at %) and equal to or smaller than about 23 at %, and a ratio of indium to zinc contained in the sacrificial pattern is about 1:1.

The barrier wall may include a first barrier wall layer disposed on the pixel definition layer and a second barrier wall layer disposed on the first barrier wall layer, and the barrier wall opening may include a first opening area defined by an inner side surface of the first barrier wall layer and a second opening area defined by an inner side surface of the second barrier wall layer and having a width smaller than a width of the first opening area.

An etch rate of the sacrificial pattern with respect to a first etchant may be smaller than an etch rate of the first barrier wall layer with respect to the first etchant.

The etch rate of the sacrificial pattern with respect to the first etchant may be smaller than about 0.5 angstroms per second (Å/sec).

The etch rate of the first barrier wall layer with respect to the first etchant may be greater than an etch rate of the second barrier wall layer with respect to the first etchant.

The first barrier wall layer may include aluminum (Al) or an aluminum alloy.

An etch rate of the sacrificial pattern with respect to a second etchant different from the first etchant may be greater than about 5 Å/sec.

The metal oxide included in the sacrificial pattern may have an amorphous structure.

The anode may include silver.

The anode may include a first layer disposed on the base layer and including indium tin oxide (“ITO”), a second layer disposed on the first layer and including silver, and a third layer disposed on the second layer and including indium tin oxide (ITO), and a crystallization degree of the indium tin oxide included in the third layer may be greater than a crystallization degree of the metal oxide included in the sacrificial pattern.

Embodiments of the invention provide a method of manufacturing a display panel. The manufacturing method of the display device includes: forming an anode on a base layer and a sacrificial pattern on the anode; forming a pixel definition layer provided with a light emitting opening to expose at least a portion of the sacrificial pattern on the base layer; forming a preliminary barrier wall on the pixel definition layer; etching the preliminary barrier wall to form a barrier wall through which a barrier wall opening overlapping the light emitting opening is defined; etching the sacrificial pattern to form a sacrificial opening through which at least a portion of the anode is exposed; and forming a light emitting pattern and a cathode in the barrier wall opening. The cathode is in contact with the barrier wall. The sacrificial pattern includes a metal oxide including tin, indium, and zinc, a tin content relative to a total content of tin, indium, and zinc contained in the sacrificial pattern is equal to or greater than about 18 at % and equal to or smaller than about 23 at %, and a ratio of indium to zinc included in the sacrificial pattern is about 1:1.

The forming of the preliminary barrier wall may include: forming a first preliminary barrier wall layer on the pixel definition layer; and forming a second preliminary barrier wall layer on the first preliminary barrier wall layer, and the etching of the preliminary barrier wall may include: first etching the preliminary barrier wall to form a preliminary barrier wall opening; and second etching the preliminary barrier wall to form the barrier wall to include a first barrier wall layer and a second barrier wall layer disposed on the first barrier wall layer.

The first etching of the preliminary barrier wall may include dry etching the first and second preliminary barrier wall layers, and the second etching of the preliminary barrier wall may include wet etching the first preliminary barrier wall layer.

A first etchant may be provided in the second etching of the preliminary barrier wall, and an etch rate of the sacrificial pattern with respect to the first etchant may be smaller than an etch rate of the first barrier wall layer with respect to the first etchant.

The etch rate of the sacrificial pattern with respect to the first etchant may be smaller than about 0.5 Å/sec.

A second etchant may be provided in the etching of the sacrificial pattern, and an etch rate of the sacrificial pattern with respect to the second etchant may be greater than about 5 Å/sec.

The etch rate of the sacrificial pattern with respect to the second etchant may be greater than an etch rate of the anode with respect to the second etchant.

The method may further include heat treating the anode and the sacrificial pattern after the forming of the anode and the sacrificial pattern and before the forming of the pixel definition layer. A crystallization degree of a metal oxide included in the anode may be greater than a crystallization degree of the metal oxide included in the sacrificial pattern in the heat treating.

The heat treating may be carried out at a temperature of about 250 to about 260 Celsius degrees for about 30 to about 60 minutes.

The forming of the anode and the sacrificial pattern may include: forming a preliminary anode layer on the base layer; forming a preliminary sacrificial pattern layer on the preliminary anode layer; and patterning the preliminary anode layer and the preliminary sacrificial pattern layer to form the anode and the sacrificial pattern, respectively.

According to the above, the sacrificial pattern is etched to a lesser extent and/or is prevented from being etched in the process of forming the barrier wall, and thus, the electrode disposed under the sacrificial pattern is effectively prevented from being damaged. Accordingly, the process reliability of the display panel is enhanced, and the display quality of the display panel is improved.

### BRIEF DESCRIPTION OF THE DRAWINGS

The above and other advantages of the present disclosure will become readily apparent by reference to the following detailed description when considered in conjunction with the accompanying drawings wherein:

FIG. 1A is a perspective view of a display device according to an embodiment of the present disclosure;

FIG. 1B is an exploded perspective view of a display device according to an embodiment of the present disclosure;

FIG. 2 is a cross-sectional view of a display panel according to an embodiment of the present disclosure;

FIG. 3 is a plan view of a display panel according to an embodiment of the present disclosure;

FIG. 4 is an enlarged plan view of a portion of a display area of a display panel according to an embodiment of the present disclosure;

FIG. 5 is a cross-sectional view of a portion of a display area of a display panel according to an embodiment of the present disclosure;

FIG. 6 is a cross-sectional view schematically illustrating a method of evaluating an etch rate of a cover layer according to embodiment examples and comparative examples of the present disclosure;

FIG. 7 is a cross-sectional view of a display panel taken along a line I-I′ of FIG. 4; and

FIGS. 8A to 8K are cross-sectional views illustrating a method of manufacturing a display panel according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms “first,” “second,” etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value. Hereinafter, embodiments of the present disclosure will be described with reference to accompanying drawings.

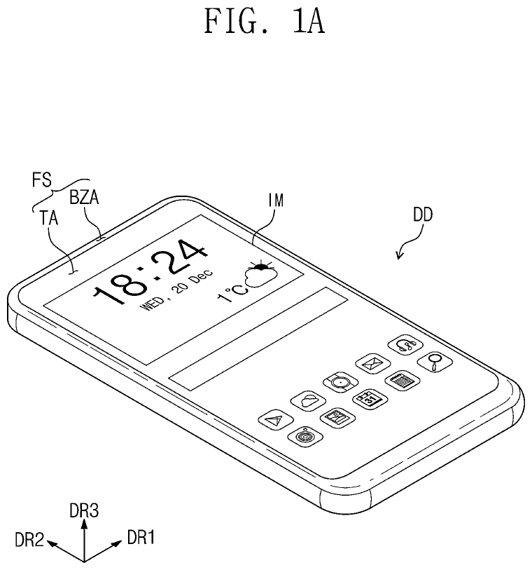

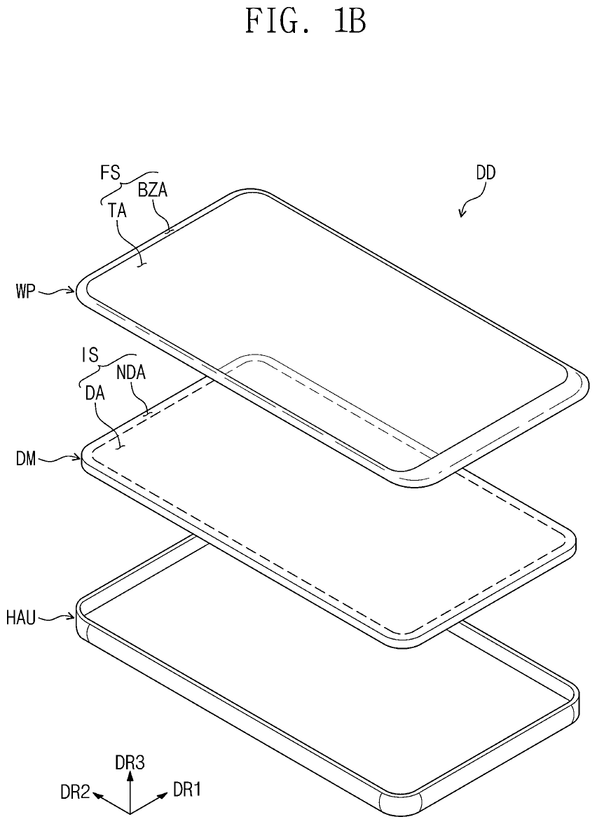

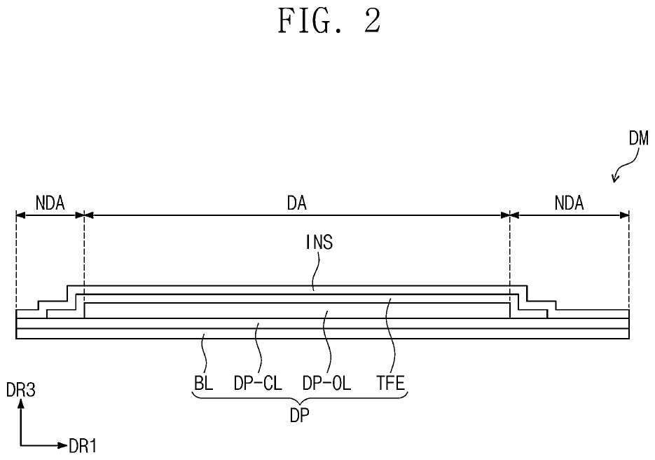

FIG. 1A is a perspective view of a display device DD according to an embodiment of the present disclosure. FIG. 1B is an exploded perspective view of the display device DD according to an embodiment of the present disclosure. FIG. 2 is a cross-sectional view of a display module DM according to an embodiment of the present disclosure.

The display device DD may be applied to a large-sized electronic item, such as a television set, a monitor, or an outdoor billboard. In addition, the display device DD may be applied to a small and medium-sized electronic item, such as a personal computer, a notebook computer, a personal digital assistant, a car navigation unit, a game unit, a smartphone, a tablet computer, and a camera. However, these are merely examples, and the display device DD may be employed in other display devices as long as they do not deviate from the concept of the present disclosure. In the present embodiment, the smartphone will be described as a representative example of the display device DD.

Referring to FIGS. 1A, 1B, and 2, the display device DD may display an image IM through a display surface FS, which is substantially parallel to each of a first direction DR1 and a second direction DR2, toward a third direction DR3. The image IM may include a video and a still image. FIG. 1A shows a clock widget and application icons as a representative example of the image IM. The display surface FS through which the image IM is displayed may correspond to a front surface of the display device DD.

In the present embodiment, front (or upper) and rear (or lower) surfaces of each member of the display device DD may be defined with respect to a direction in which the image IM is displayed. The front and rear surfaces may be opposite to each other in the third direction DR3, and a normal line direction of each of the front and rear surfaces may be substantially parallel to the third direction DR3. Directions indicated by the first, second, and third directions DR1, DR2, and DR3 may be relative to each other, and thus, the directions indicated by the first, second, and third directions DR1, DR2, and DR3 may be changed to other directions. In the following descriptions, the expression “when viewed in a plane” means a state of being viewed in the third direction DR3 (i.e., plan view).

Referring to FIG. 1B, the display device DD may include a window WP, a display module DM, and a housing HAU. The window WP and the housing HAU may be coupled to each other to provide an exterior of the display device DD.

The window WP may include an optically transparent insulating material. For example, the window WP may include a glass or plastic material. A front surface of the window WP may define the display surface FS of the display device DD. The display surface FS may include a transmissive area TA and a bezel area BZA. The transmissive area TA may be an optically transparent area. For example, the transmissive area TA may be an area having a visible light transmittance of about 90% or more.

The bezel area BZA may be an area having a relatively lower light transmittance than light transmittance of the transmissive area TA. The bezel area BZA may define a shape of the transmissive area TA. The bezel area BZA may be disposed adjacent to the transmissive area TA and may surround the transmissive area TA. However, this is merely one example, and the bezel area BZA may be omitted from the window WP according to the embodiment of the present disclosure. The window WP may include at least one functional layer of an anti-fingerprint layer, a hard coating layer, and an anti-reflective layer and should not be particularly limited.

The display module DM may be disposed under the window WP. The display module DM may have a configuration that substantially generates the image IM. The image IM generated by the display module DM may be displayed through a display surface IS of the display module DM and may be viewed by a user through the transmissive area TA.

The display module DM may include a display area DA and a non-display area NDA. The display area DA may be activated in response to electrical signals. The non-display area NDA may be adjacent to the display area DA. The non-display area NDA may surround the display area DA. The non-display area NDA may be covered by the bezel area BZA and may not be viewed from the outside.

As shown in FIG. 2, the display module DM may include a display panel DP and an input sensor INS. Although not shown in figures, the display device DD (refer to FIG. 1A) may further include a protective member disposed on a lower surface of the display panel DP or an anti-reflective member and/or a window member disposed on an upper surface of the input sensor INS.

The display panel DP may be a light emitting type display panel, however, it should not be particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The display panel DP may include a base layer BL, a circuit element layer DP-CL, a display element layer DP-OL, and a thin film encapsulation layer TFE. The circuit element layer DP-CL, the display element layer DP-OL, and the thin film encapsulation layer TFE may be disposed on the base layer BL. The input sensor INS may be disposed directly on the thin film encapsulation layer TFE. In the present disclosure, the expression “A component A is disposed directly on a component B.” means that no adhesive layers are present between the component A and the component B.

The base layer BL may include at least one plastic film. The base layer BL may be a flexible substrate and may include a plastic substrate, a glass substrate, a metal substrate, or an organic/inorganic composite material substrate. In the present disclosure, the display area DA and the non-display area NDA described with reference to FIG. 1B may be defined in the base layer BL of FIG. 2.

The circuit element layer DP-CL may include at least one insulating layer and a circuit element. The insulating layer may include at least one inorganic layer and at least one organic layer. The circuit element may include signal lines and a pixel driving circuit.

The display element layer DP-OL may include a barrier wall and a light emitting element. The light emitting element may include an anode, a light emitting pattern, and a cathode.

The thin film encapsulation layer TFE may include a plurality of thin layers. Some thin layers may be disposed to improve an optical efficiency, and some thin layers may be disposed to protect organic light emitting diodes.

The input sensor INS may obtain coordinate information of an external input. The input sensor INS may have a multi-layer structure. The input sensor INS may include a conductive layer having a single-layer or multi-layer structure. The input sensor INS may include an insulating layer having a single-layer or multi-layer structure. The input sensor INS may sense the external input by a capacitive method. However, the operation method of the input sensor INS should not be particularly limited. The input sensor INS may sense the external input by an electromagnetic induction method or a pressure sensing method. Meanwhile, according to an embodiment, the input sensor INS may be omitted.

As shown in FIG. 1B, the housing HAU may be coupled with the window WP. The housing HAU and the window WP coupled to the housing HAU may provide a predetermined inner space. The display module DM may be accommodated in the inner space.

The housing HAU may include a material with a relatively high rigidity. For example, the housing HAU may include a glass, plastic, or metal material or a plurality of frames and/or plates of combinations thereof. The housing HAU may stably protect the components of the display device DD accommodated in the inner space from external impacts.

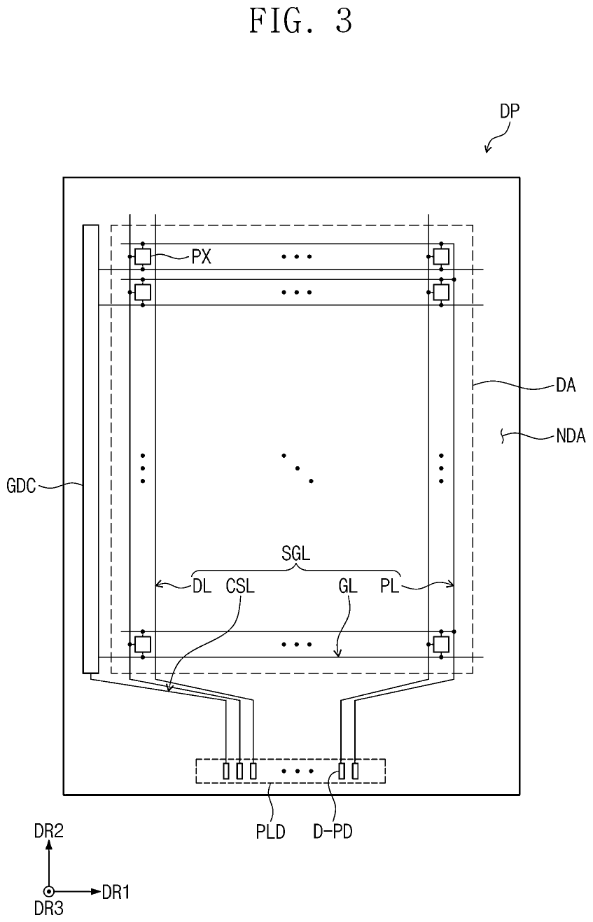

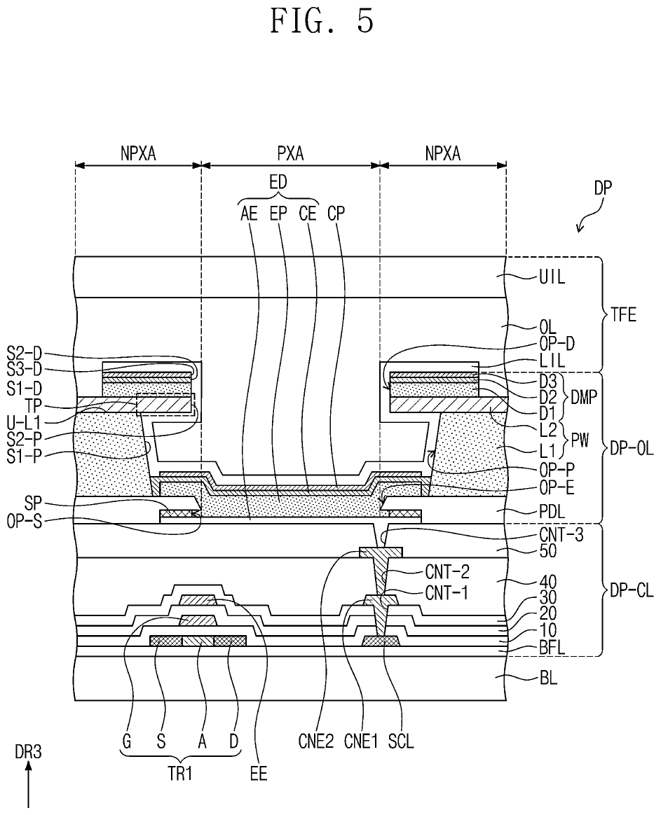

FIG. 3 is a plan view of the display panel DP according to an embodiment of the present disclosure. As used herein, the “plan view” is a view in a thickness direction (i.e., the third direction DR3) of a base layer BL (See FIG. 5).

Referring to FIG. 3, the display panel DP may include the display area DA and the non-display area NDA around the display area DA. The display panel DP may include pixels PX disposed in the display area DA and signal lines SGL electrically connected to the pixels PX. The display panel DP may include a driving circuit GDC and a pad part PLD. The display area DA and the non-display area NDA may be distinguished from each other by a presence or absence of the pixels PX. The pixels PX may be disposed in the display area DA. The driving circuit GDC and the pad part PLD may be disposed in the non-display area NDA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate gate signals and may sequentially output the generated gate signals to the gate lines GL. The gate driving circuit may further output another control signal to the pixel driving circuit.

The pad part PLD may be connected to a flexible circuit board (not shown). The pad part PLD may include pixel pads D-PD, and the pixel pads D-PD may be pads that connect the flexible circuit board to the display panel DP. Each of the pixel pads D-PD may be connected to a corresponding signal line among the signal lines SGL. The pixel pads D-PD may be connected to corresponding pixels PX via the signal lines SGL. In addition, one pixel pad among the pixel pads D-PD may be connected to the driving circuit GDC.

In addition, the pad part PLD may further include input pads. The input pads may be pads that connect the flexible circuit board (not shown) to the input sensor INS (refer to FIG. 2), however, the present disclosure should not be limited thereto or thereby. According to an embodiment, the input pads may be disposed in the input sensor INS (refer to FIG. 2) and may be connected to a separate circuit board different from the flexible circuit board to which the pixel pads D-PD are connected. According to an embodiment, the input sensor INS (refer to FIG. 2) may be omitted and may not further include the input pads.

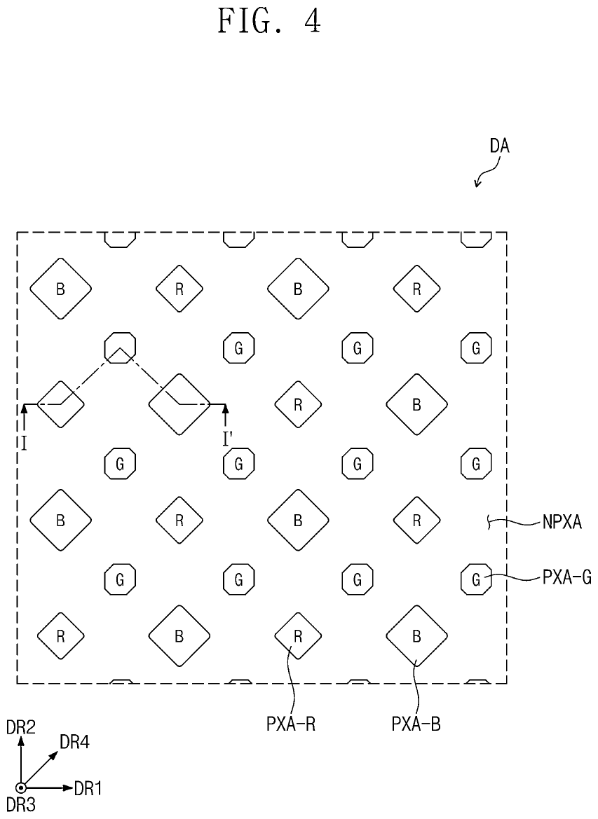

FIG. 4 is an enlarged plan view of a portion of the display area DA of the display panel according to an embodiment of the present disclosure. FIG. 4 is a plan view showing the display module DM when viewed from the above of the display surface IS (refer to FIG. 1B) of the display module DM (refer to FIG. 1B) and shows an arrangement of light emitting areas PXA-R, PXA-G, and PXA-B.

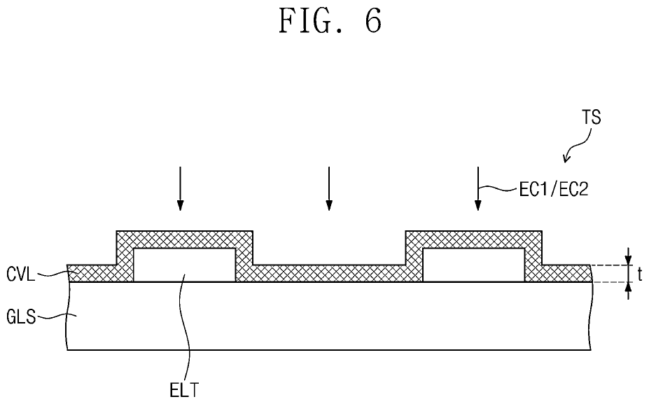

Referring to FIG. 4, the display area DA may include first, second, and third light emitting areas PXA-R, PXA-G, and PXA-B and a peripheral area NPXA surrounding the first, second, and third light emitting areas PXA-R, PXA-G, and PXA-B. The first, second, and third light emitting areas PXA-R, PXA-G, and PXA-B may correspond to areas from which lights provided from light emitting elements ED1, ED2, and ED3 (refer to FIG. 6) are emitted, respectively. The first, second, and third light emitting areas PXA-R, PXA-G, and PXA-B may be distinguished by colors of the lights emitted outward from the display module DM (refer to FIG. 2).

The first, second, and third light emitting areas PXA-R, PXA-G, and PXA-B may provide first, second, and third color lights having colors different from each other, respectively. As an example, the first color light may be a red light, the second color light may be a green light, and the third color light may be a blue light. However, the first, second, and third color lights should not be limited thereto or thereby.

Each of the first, second, and third light emitting areas PXA-R, PXA-G, and PXA-B may be defined as an area through which an upper surface of the anode is exposed by a light emitting opening described later. The peripheral area NPXA may define a boundary between the first, second, and third light emitting areas PXA-R, PXA-G, and PXA-B and may prevent a mixture of the colors of the lights between the first, second, and third light emitting areas PXA-R, PXA-G, and PXA-B.

Each of the first, second, and third light emitting areas PXA-R, PXA-G, and PXA-B may be provided in plural and may be repeatedly arranged in a predetermined arrangement within the display area DA. As an example, the first and third light emitting areas PXA-R and PXA-B may be alternately arranged with each other in the first direction DR1 to form a first group. The second light emitting areas PXA-G may be arranged in the first direction DR1 to form a second group. Each of the first group and the second group may be provided in plural, and the first groups may be alternately arranged with the second groups in the second direction DR2.

One second light emitting area PXA-G may be disposed spaced apart from one first light emitting area PXA-R or one third light emitting area PXA-B in a fourth direction DR4. The fourth direction DR4 may correspond to a direction between the first and second directions DR1 and DR2.

FIG. 4 shows a representative example of the arrangement of the first, second, and third light emitting areas PXA-R, PXA-G, and PXA-B, and the arrangement of the first, second, and third light emitting areas PXA-R, PXA-G, and PXA-B should not be particularly limited and may be changed in various ways. The first, second, and third light emitting areas PXA-R, PXA-G, and PXA-B may be arranged in a pentile pattern (PENTILE™) as shown in FIG. 4. According to an embodiment, the first, second, and third light emitting areas PXA-R, PXA-G, and PXA-B may be arranged in a stripe pattern or a diamond pattern (Diamond Pixel™).

Each of the first, second, and third light emitting areas PXA-R, PXA-G, and PXA-B may have a variety of shapes when viewed in a plane. As an example, each of the first, second, and third light emitting areas PXA-R, PXA-G, and PXA-B may have a polygonal shape, a circular shape, or an oval shape. In FIG. 4, the first and third light emitting areas PXA-R and PXA-B each having a quadrangular shape (or a lozenge shape) and the second light emitting area PXA-G having an octagonal shape are shown as a representative example.

The first, second, and third light emitting areas PXA-R, PXA-G, and PXA-B may have substantially the same shape as each other when viewed in the plane, or at least one of the first, second, and third light emitting areas PXA-R, PXA-G, and PXA-B may have a shape different from the others. FIG. 4 shows a structure in which the first and third light emitting areas PXA-R and PXA-B have the same shape as each other when viewed in the plane and the second light emitting area PXA-G has the shape different from shapes of the first and third light emitting areas PXA-R and PXA-B as a representative example.

At least one of the first, second, and third light emitting areas PXA-R, PXA-G, and PXA-B may have a size different from those of the others when viewed in the plane. The size of the first light emitting area PXA-R emitting the red light may be greater than the size of the second light emitting area PXA-G emitting the green light and may be smaller than the size of the third light emitting area PXA-B emitting the blue light. However, a size relationship between the first, second, and third light emitting areas PXA-R, PXA-G, and PXA-B according to the colors of the emitted lights should not be limited thereto or thereby and may be changed in various ways depending on a design of the display module DM (refer to FIG. 2). In addition, according to an embodiment, the first, second, and third light emitting areas PXA-R, PXA-G, and PXA-B may have substantially the same size as each other when viewed in the plane.

In other embodiments, the shape, size, and arrangement of the first, second, and third light emitting areas PXA-R, PXA-G, and PXA-B of the display module DM (refer to FIG. 2) may be variously designed depending on the colors of the emitted lights, the size of the display module DM (refer to FIG. 2), and the configuration of the display module DM (refer to FIG. 2), and they should not be limited to the embodiment shown in FIG. 4.

FIG. 5 is a cross-sectional view of the display panel DP according to an embodiment of the present disclosure. In FIG. 5, the same reference numerals denote the same elements in FIG. 2, and thus, detailed descriptions of the same elements will be omitted.

FIG. 5 is an enlarged view of one light emitting area PXA of the display area DA (refer to FIG. 4), and the light emitting area PXA of FIG. 5 corresponds to one of the first, second, and third light emitting areas PXA-R, PXA-G, and PXA-B of FIG. 4.

Referring to FIG. 5, the display panel DP may include the base layer BL, the circuit element layer DP-CL, the display element layer DP-OL, and the thin film encapsulation layer TFE.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by a photolithography process and an etching process. The semiconductor pattern, the conductive pattern, and the signal line included in the circuit element layer DP-CL and the display element layer DP-OL may be formed through the above processes.

The circuit element layer DP-CL may be disposed on the base layer BL. The circuit element layer DP-CL may include a buffer layer BFL, a transistor TR1, a signal transmission area SCL, first, second, third, fourth, and fifth insulating layers 10, 20, 30, 40, and 50, an upper electrode EE, and a plurality of connection electrodes CNE1 and CNE2.

The buffer layer BFL may be disposed on the base layer BL. The buffer layer BFL may increase an adhesion between the base layer BL and the semiconductor pattern. The buffer layer BFL may include a silicon oxide layer and a silicon nitride layer, and the silicon oxide layer and the silicon nitride layer may be alternately stacked with each other.

The semiconductor pattern may be disposed on the buffer layer BFL. The semiconductor pattern may include polysilicon, however, it should not be limited thereto or thereby. The semiconductor pattern may include an amorphous silicon or metal oxide. FIG. 5 shows a portion of the semiconductor pattern, and the semiconductor pattern may be further disposed in the light emitting areas PXA-R, PXA-G, and PXA-B (refer to FIG. 4). The semiconductor pattern may be arranged with a specific rule over the light emitting areas PXA-R, PXA-G, and PXA-B (refer to FIG. 4). The semiconductor pattern may have different electrical properties depending on whether it is doped or not or whether it is doped with an N-type dopant or a P-type dopant. The semiconductor pattern may include a first region having a relatively high doping concentration and a second region having a relatively low doping concentration. The first region may be doped with the N-type dopant or the P-type dopant. A P-type transistor may include the first region doped with the P-type dopant.

The first region may have a conductivity greater than a conductivity of the second region and may substantially serve as an electrode or a signal line. The second region may substantially correspond to an active (or a channel) of the transistor. In other words, a portion of the semiconductor pattern may be the active of the transistor, another portion of the semiconductor pattern may be a source or a drain of the transistor, and the other portion of the semiconductor pattern may be a conductive area.

A source S, an active A, and a drain D of the transistor TR1 may be formed from the semiconductor pattern. FIG. 5 shows a portion of the signal transmission area SCL formed from the semiconductor pattern. Although not shown in figures, the signal transmission area SCL may be connected to the drain D of the transistor TR1 in a plane.

The first, second, third, fourth, and fifth insulating layers 10, 20, 30, 40, and 50 may be disposed on the buffer layer BFL. Each of the first to fifth insulating layers 10 to 50 may be an inorganic layer or an organic layer.

The first insulating layer 10 may be disposed on the buffer layer BFL. The first insulating layer 10 may cover the source S, the active A, and the drain D of the transistor TR1 and the signal transmission area SCL disposed on the buffer layer BFL. A gate G of the transistor TR1 may be disposed on the first insulating layer 10. The second insulating layer 20 may be disposed on the first insulating layer 10 and may cover the gate G. The upper electrode EE may be disposed on the second insulating layer 20. The third insulating layer 30 may be disposed on the second insulating layer 20 and may cover the upper electrode EE.

A first connection electrode CNE1 may be disposed on the third insulating layer 30. The first connection electrode CNE1 may be connected to the signal transmission area SCL via a contact hole CNT-1 defined through the first, second, and third insulating layers 10, 20, and 30. The fourth insulating layer 40 may be disposed on the third insulating layer 30 and may cover the first connection electrode CNE1. The fourth insulating layer 40 may be an organic layer.

A second connection electrode CNE2 may be disposed on the fourth insulating layer 40. The second connection electrode CNE2 may be connected to the first connection electrode CNE1 via a contact hole CNT-2 defined through the fourth insulating layer 40. The fifth insulating layer 50 may be disposed on the fourth insulating layer 40 and may cover the second connection electrode CNE2. The fifth insulating layer 50 may be an organic layer.

The display element layer DP-OL may be disposed on the circuit element layer DP-CL. The display element layer DP-OL may include the light emitting element ED, a sacrificial pattern SP, a pixel definition layer PDL, the barrier wall PW, and dummy patterns DMP.

The light emitting element ED may include an anode AE (or a first electrode), the light emitting pattern EP, and a cathode CE (or a second electrode). Each of first, second, and third light emitting elements ED1, ED2, and ED3 described later may have substantially the same configuration as the configuration of the light emitting element ED of FIG. 5. Descriptions on the anode AE, the light emitting pattern EP, and the cathode CE may be equally applied to the anode, the light emitting pattern, and the cathode of each of the first to third light emitting elements.

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 via a connection contact hole CNT-3 defined through the fifth insulating layer 50. Accordingly, the anode AE may be electrically connected to the signal transmission area SCL via the first and second connection electrodes CNE1 and CNE2 and may be electrically connected to a corresponding circuit element. The anode AE may have a single-layer or multi-layer structure. According to an embodiment, the anode AE may include silver (Ag). The anode AE may include plural layers containing ITO or Ag. As an example, the anode AE may include a first layer (or a lower ITO layer) containing ITO, a second layer (or an Ag layer) disposed on the lower ITO layer and containing Ag, and a third layer (or an upper ITO layer) disposed on the Ag layer and containing ITO.

The anode AE may have a crystalline structure. As an example, the anode AE may have a single-crystalline structure or a polycrystalline structure. When the anode AE includes a plurality of layers, at least one of the plural layers included in the anode AE may have the crystalline structure. According to an embodiment, a metal oxide included in the anode AE may have the crystalline structure. According to an embodiment, a layer disposed at an uppermost layer among the plural layers included in the anode AE may have the crystalline structure. That is, the layer that is in contact with the sacrificial pattern SP among the layers included in the anode AE may have the crystalline structure.

The sacrificial pattern SP may be disposed between the anode AE and the pixel definition layer PDL. The sacrificial pattern SP may correspond to a portion of a layer provided to prevent the anode AE from being damaged in a process of forming a barrier wall opening OP-P described later. The sacrificial pattern SP may be provided with a sacrificial opening OP-S defined therethrough to expose a portion of the upper surface of the anode AE. The sacrificial opening OP-S may overlap a light emitting opening OP-E described later in a plan view.

The pixel definition layer PDL may be disposed on the fifth insulating layer 50 of the circuit element layer DP-CL. The pixel definition layer PDL may be provided with the light emitting opening OP-E defined therethrough. The light emitting opening OP-E may correspond to the anode AE, and at least a portion of the anode AE may be exposed through the light emitting opening OP-E of the pixel definition layer PDL.

In addition, the light emitting opening OP-E may correspond to the sacrificial opening OP-S of the sacrificial pattern SP. According to the present embodiment, the upper surface of the anode AE may be spaced apart from the pixel definition layer PDL with the sacrificial pattern SP interposed therebetween when viewed in a cross-section, and thus, the anode AE may be prevented from being damaged in a process of forming the light emitting opening OP-E.

When viewed in the plane, a size of the light emitting opening OP-E may be smaller than a size of the sacrificial opening OP-S. That is, an inner side surface of the pixel definition layer PDL, which defines the light emitting opening OP-E, may be closer to a center of the anode AE than an inner side surface of the sacrificial pattern SP, which defines the sacrificial opening OP-S, is. However, the present disclosure should not be limited thereto or thereby. According to an embodiment, the inner side surface of the sacrificial pattern SP, which defines the sacrificial opening OP-S, may be substantially aligned with the inner side surface of the pixel definition layer PDL, which defines the corresponding light emitting opening OP-E. In this case, the light emitting area PXA may be an area of the anode AE exposed through the corresponding sacrificial opening OP-S.

The pixel definition layer PDL may include an inorganic insulating material. The pixel definition layer PDL may include at least one of silicon oxide (SiOₓ), silicon nitride (SiNₓ), and silicon oxynitride (SiOₓN_{y}). As an example, the pixel definition layer PDL may include silicon nitride (SiNₓ). The pixel definition layer PDL may be disposed between the anode AE and the barrier wall PW and may block the anode AE from being electrically connected to the barrier wall PW, however, the present disclosure should not be limited thereto or thereby. According to an embodiment, the pixel definition layer PDL may include an organic insulating material. In addition, the pixel definition layer PDL may have a single-layer structure or a multi-layer structure. When the pixel definition layer PDL includes a plurality of layers, the layers may include different materials from each other.

The barrier wall PW may be disposed on the pixel definition layer PDL. The barrier wall PW may be provided with the barrier wall opening OP-P defined therethrough. The barrier wall opening OP-P may correspond to the light emitting opening OP-E, and at least a portion of the anode AE may be exposed through the barrier wall opening OP-P.

The barrier wall PW may have an undercut shape in the cross-section. The barrier wall PW may include a plurality of layers sequentially stacked, and at least one of the layers may be recessed relative to adjacent layers. At least one of the layers included in the barrier wall PW may protrude relative to adjacent layers. Accordingly, the barrier wall PW may include a tip portion.

The barrier wall PW may include a first barrier wall layer L1 and a second barrier wall layer L2. The first barrier wall layer L1 may be disposed on the pixel definition layer PDL, and the second barrier wall layer L2 may be disposed on the first barrier wall layer L1. The first barrier wall layer L1 may be recessed relative to the second barrier wall layer L2 with respect to the light emitting area PXA. That is, the first barrier wall layer L1 may be undercut with respect to the second barrier wall layer L2.

FIG. 5 shows a structure in which the barrier wall PW includes only the first barrier wall layer L1 and the second barrier wall layer L2, however, it should not be limited thereto or thereby. According to an embodiment, a third barrier wall layer may be further disposed on the second barrier wall layer L2, or the third barrier wall layer may be further disposed under the first barrier wall layer L1, and it should not be limited thereto or thereby.

The first barrier wall layer L1 may have conductivity. The first barrier wall layer L1 may include a conductive material. In the present embodiment, the first barrier wall layer L1 may include aluminum (Al). As an example, the first barrier wall layer L1 may include a pure aluminum or aluminum alloy. As an example, the aluminum alloy may include a small amount of nickel (Ni). As an example, a nickel content relative to total metal elements included in the aluminum alloy may be equal to or smaller than about 0.5 atomic percent (at %), and an aluminum content relative to total metal elements included in the aluminum alloy may be equal to or greater than about 99.5 at %.

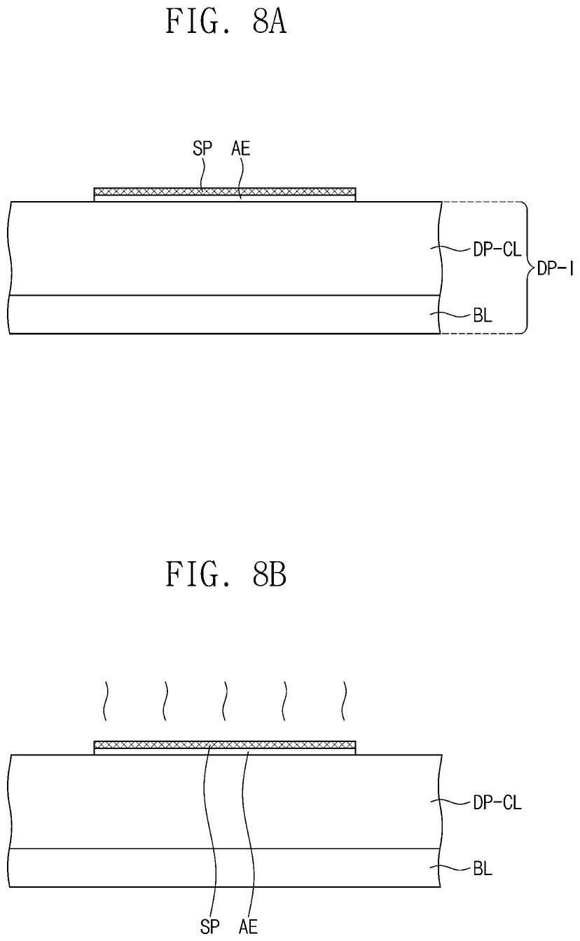

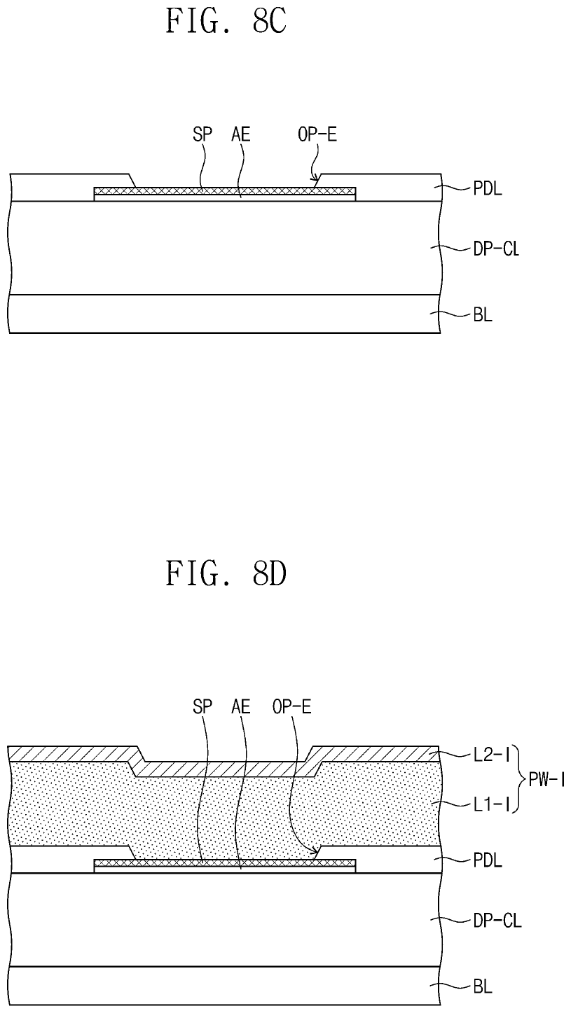

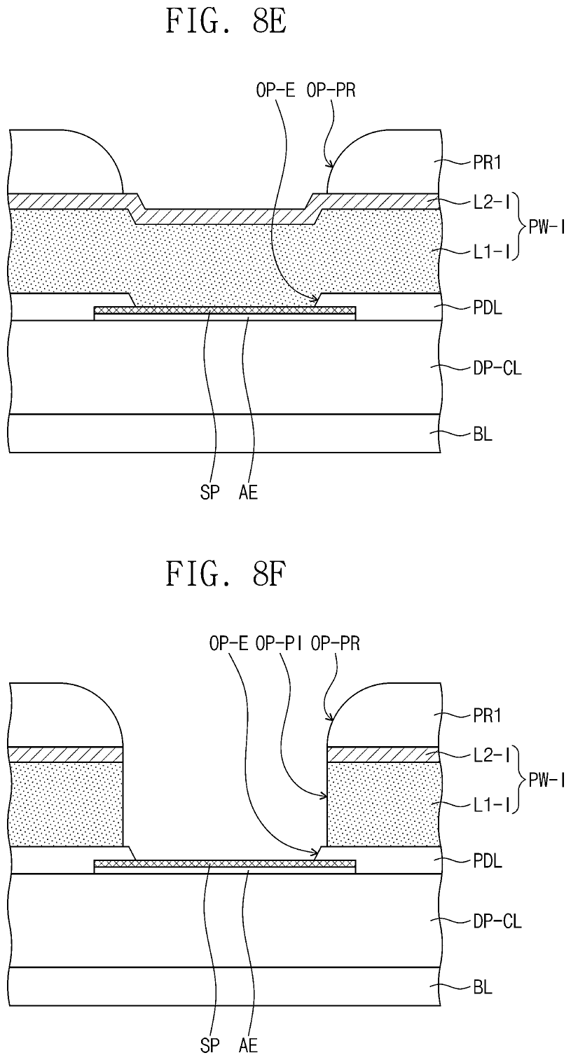

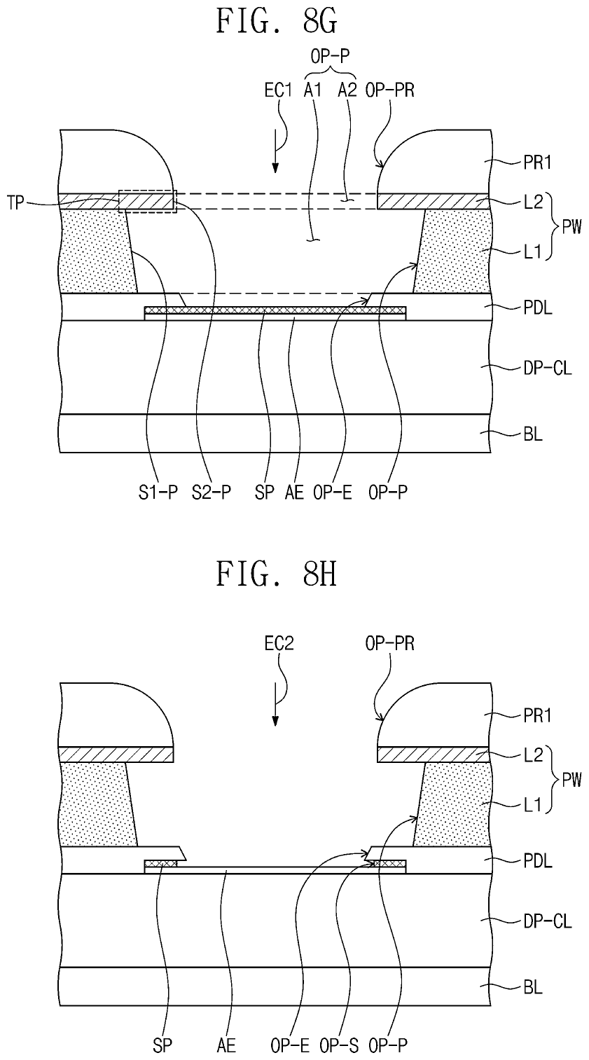

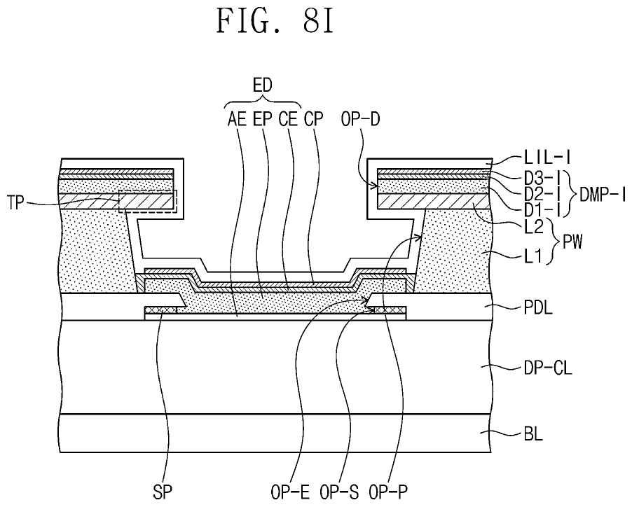

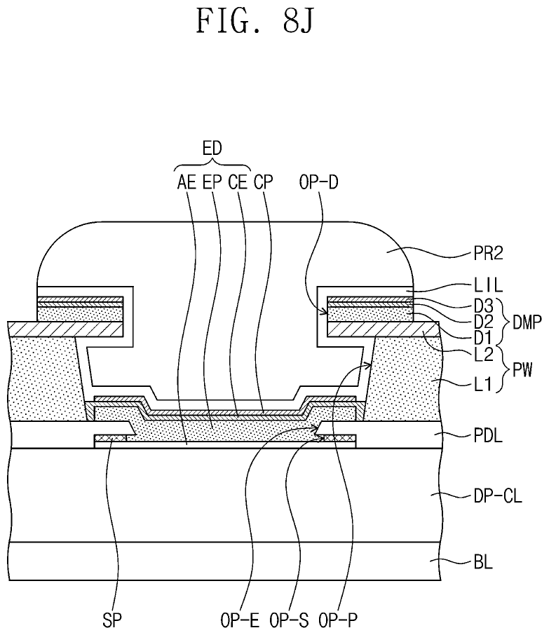

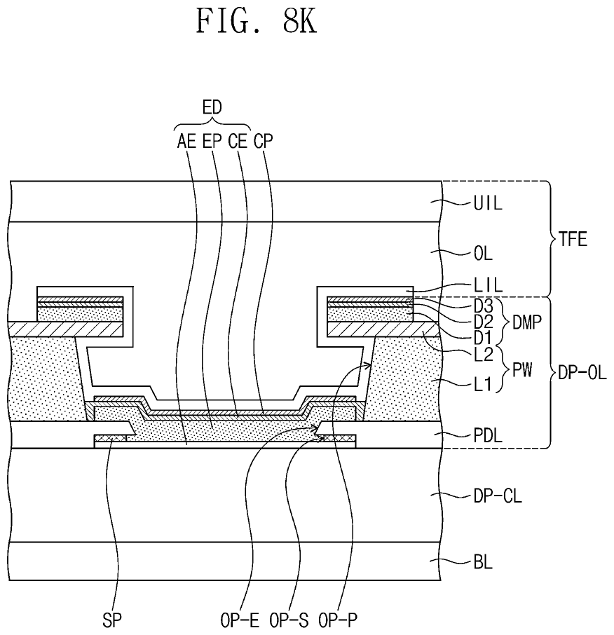

The second barrier wall layer L2 may be disposed on the first barrier wall layer L1. The second barrier wall layer L2 may include a material having an etch selectivity with respect to the first barrier wall layer L1. As an example, a reactivity of the second barrier wall layer L2 with respect to an etchant EC1 (refer to FIG. 8G) used in the process of forming the barrier wall PW may be smaller than a reactivity of the first barrier wall layer L1 with respect to the etchant EC1 (refer to FIG. 8G) used in the process of forming the barrier wall PW. The first barrier wall layer L1 may be recessed relative to the second barrier wall layer L2 with respect to the light emitting area PXA. The second barrier wall layer L2 may define the tip portion TP formed in the barrier wall PW.

The tip portion TP of the barrier wall PW may be defined as a portion of the second barrier wall layer L2, which protrudes to the light emitting area PXA compared with the first barrier wall layer L1. In the present embodiment, an upper surface of the second barrier wall layer L2 may correspond to an uppermost surface of the barrier wall PW and may define an upper surface of the tip portion TP formed in the barrier wall PW.

The second barrier wall layer L2 may include a conductive material. As an example, the conductive material may include metal, metal nitride, transparent conductive oxide (“TCO”), or a combination thereof. As an example, the second barrier wall layer L2 may include titanium (Ti), however, a material for the second barrier wall layer L2 should not be particularly limited. Various materials may be applied to the second barrier wall layer L2 as long as the materials for the second barrier wall layer L2 have an etch selectivity with respect to the first barrier wall layer L1 when exposed to the etchant EC1 (refer to FIG. 8G). As an example, the second barrier wall layer L2 may not include a metal material.

The barrier wall opening OP-P defined through the barrier wall PW may include a first opening area A1 (refer to FIG. 8G) and a second opening area A2 (refer to FIG. 8G). The first barrier wall layer L1 may include a first inner side surface S1-P that defines the first opening area A1 (refer to FIG. 8G) of the barrier wall opening OP-P, and the second barrier wall layer L2 may include a second inner side surface S2-P that defines the second opening area A2 (refer to FIG. 8G).

The first inner side surface S1-P of the first barrier wall layer L1 may be recessed inward relative to the second inner side surface S2-P of the second barrier wall layer L2. When viewed in the plane, the second inner side surface S2-P of the second barrier wall layer L2, which defines the second opening area A2 (refer to FIG. 8G), may protrude relative to the first inner side surface S1-P of the first barrier wall layer L1, which defines the first opening area A1 (refer to FIG. 8G), and may be adjacent to the center of the anode AE. The first opening area A1 (refer to FIG. 8G) may have a width different from a width of the second opening area A2 (refer to FIG. 8G). The width of the second opening area A2 (refer to FIG. 8G) may be smaller than the width of the first opening area A1 (refer to FIG. 8G).

FIG. 5 shows a structure in which the first inner side surface S1-P of the first barrier wall layer L1 has a tapered shape with respect to an upper surface of the pixel definition layer PDL as a representative example, however, the present disclosure should not be limited thereto or thereby. As an example, the first inner side surface S1-P may have a sidewall extending vertically or may have a reverse tapered shape. In addition, FIG. 5 shows a structure in which the second inner side surface S2-P of the second barrier wall layer L2 extends vertically with respect to the upper surface of the pixel definition layer PDL as a representative example, however, the present disclosure should not be limited thereto or thereby. As an example, the second inner side surface S2-P may have a tapered shape or a reverse tapered shape with respect to the upper surface of the pixel definition layer PDL.

The light emitting pattern EP may be disposed on the anode AE. The light emitting pattern EP may include a light emitting layer including a light emitting material. The light emitting pattern EP may further include a hole injection layer and a hole transport layer disposed between the anode AE and the light emitting layer and may further include an electron transport layer and an electron injection layer, which are disposed on the light emitting layer. The light emitting pattern EP may be referred to as an organic layer or an intermediate layer.

The light emitting pattern EP may be patterned by the tip portion defined in the barrier wall PW. The light emitting pattern EP may be disposed inside the sacrificial opening OP-S, the light emitting opening OP-E, and the barrier wall opening OP-P. The light emitting pattern EP may cover a portion of the upper surface of the pixel definition layer PDL, which is exposed without being covered by the barrier wall opening OP-P.

The cathode CE may be disposed on the light emitting pattern EP. The cathode CE may be patterned by the tip portion defined in the barrier wall PW. The cathode CE may be in contact with the first inner side surface S1-P of the first barrier wall layer L1.

The barrier wall PW may receive a bias voltage (or a common voltage). Accordingly, the cathode CE may be electrically connected to the barrier wall PW, and thus, the cathode CE may receive the bias voltage (or the common voltage) from the barrier wall PW.

According to the present disclosure, the sacrificial pattern SP may include tin (Sn), indium (In), and zinc (Zn). The sacrificial pattern SP may include zinc indium tin oxide (“ZITO”). The composition of the elements included in the sacrificial pattern SP may be identified through methods, such as ICP, XPS, and SIMS.

A tin content relative to total metal elements included in the sacrificial pattern SP may be equal to or greater than about 18 at % and equal to or smaller than about 23 at %. The tin content relative to the total content of tin, indium, and zinc contained in the sacrificial pattern SP may be equal to or greater than about 18 at % and equal to or smaller than about 23 at %.

When the tin content relative to total metal elements included in the sacrificial pattern SP is smaller than about 18 at %, an etch rate of the sacrificial pattern SP may increase with respect to the etchant EC1 (refer to FIG. 8G, hereinafter, referred to as a “first etchant”) injected when a wet etching process is performed to form the barrier wall PW. Accordingly, when the wet etching process is performed to form the barrier wall PW, the sacrificial pattern SP may be etched, and the anode AE exposed without being covered by the sacrificial pattern SP may be damaged.

When the tin content relative to total metal elements included in the sacrificial pattern SP is greater than about 23 at %, an etch rate of the sacrificial pattern SP may decrease with respect to an etchant EC2 (refer to FIG. 8H, hereinafter, referred to as a “second etchant”) injected when a wet etching process is performed to form the sacrificial opening OP-S through the sacrificial pattern SP. Accordingly, it is difficult to form the sacrificial opening OP-S through the sacrificial pattern SP, and the anode AE may be covered by the sacrificial pattern SP and may not be exposed after forming the barrier wall PW.

A ratio of indium to zinc in the sacrificial pattern SP may be about 1:1.

The sacrificial pattern SP may have a thickness equal to or greater than about 100 micrometers and equal to or smaller than about 500 micrometers.

The first barrier wall layer L1 and the second barrier wall layer L2 may have different etch rates with respect to the first etchant EC1 (refer to FIG. 8G). The first barrier wall layer L1 may be etched with a first etch rate with respect to the first etchant EC1 (refer to FIG. 8G), the second barrier wall layer L2 may be etched with a second etch rate with respect to the first etchant EC1 (refer to FIG. 8G), and the second etch rate may be lower than the first etch rate. That is, the first barrier wall layer L1 and the second barrier wall layer L2 may have the etch selectivity with respect to the first etchant EC1 (refer to FIG. 8G). In the wet etching process to form the barrier wall PW, the second barrier wall layer L2 may not be etched or may not be substantially etched, and the first barrier wall layer L1 may be mainly etched due to the etch rate of the second barrier wall layer L2, which is lower than the etch rate of the first barrier wall layer L1. Accordingly, the second barrier wall layer L2 may define the tip portion TP formed in the barrier wall PW.

In addition, the sacrificial pattern SP and the first barrier wall layer L1 may have different etch rates from each other with respect to the first etchant EC1. The sacrificial pattern SP may be etched with a third etch rate with respect to the first etchant EC1 (refer to FIG. 8G), and the third etch rate may be lower than the first etch rate. That is, the sacrificial pattern SP and the first barrier wall layer L1 may have an etch selectivity with respect to the first etchant EC1 (refer to FIG. 8G). In the etching process to form the barrier wall PW, the sacrificial pattern SP may not be etched or may not be substantially etched due to the etch rate of the sacrificial pattern SP, which is lower than the etch rate of the first barrier wall layer L1. Accordingly, in the etching process to form the barrier wall PW, the anode AE may be covered by the sacrificial pattern SP not to be exposed and may be prevented from being damaged.

The first etchant EC1 (refer to FIG. 8G) may include orthophosphoric acid, acetic acid, and nitric acid. In addition, the first etchant EC1 (refer to FIG. 8G) may further include materials rather than orthophosphoric acid, acetic acid, and nitric acid.

The sacrificial pattern SP and the anode AE may have different etch rates with respect to the second etchant EC2 (refer to FIG. 8H). The sacrificial pattern SP may be etched with a fourth etch rate with respect to the second etchant EC2 (refer to FIG. 8H), the anode AE may be etched with a fifth etch rate with respect to the second etchant EC2 (refer to FIG. 8H), and the fifth etch rate may be lower than the fourth etch rate. That is, the sacrificial pattern SP and the anode AE may have an etch selectivity with respect to the second etchant EC2 (refer to FIG. 8H). In the etching process to form the sacrificial pattern SP, the anode AE may not be etched or may not be substantially etched due to the etch rate of the anode AE, which is lower than the etch rate of the sacrificial pattern SP. Accordingly, even though the anode AE is exposed through the sacrificial opening OP-S without being covered by the sacrificial pattern SP, the anode AE may be prevented from being damaged due to the second etchant EC2 (refer to FIG. 8H).

The second etchant EC2 (refer to FIG. 8H) may include water, nitric acid, and sulfuric acid. In addition, the second etchant EC2 (refer to FIG. 8H) may further include materials rather than water, nitric acid, and sulfuric acid.

The etch rate of the sacrificial pattern SP with respect to the first etchant EC1 (refer to FIG. 8G) may be smaller than about 0.5 Å/s. In this case, the sacrificial pattern SP may include zinc indium tin oxide (ZITO) and the tin content relative to total metal elements in the composition of the sacrificial pattern SP is equal to or greater than about 18 at % and equal to or smaller than about 23 at %. The etch rate of the sacrificial pattern SP with respect to the second etchant EC2 (refer to FIG. 8H) may be greater than about 5 Å/s. In this case, the sacrificial pattern SP may include zinc indium tin oxide (ZITO) and the tin content relative to total metal elements in the composition of the sacrificial pattern SP is equal to or greater than about 18 at % and equal to or smaller than about 23 at %. The “etch rate” of the sacrificial pattern SP may refer to an amount etched in a thickness direction of a film per second. The “etch rate” may refer to how fast a material is removed at a room temperature of about 25 degrees in Celsius (° C.). The “etch rate” may be expressed in units of Å/s. The etch rate may be calculated by the following Equation 1:

$$etch rate = T 1 - T 2 / S 1 \qquad Equation 1$$

In Equation 1, T1 denotes an initial film thickness before etching, T2 denotes a film thickness after etching, and S1 denotes a time during which the film is exposed to the etchant and is given in units of seconds.

The etch rate of the sacrificial pattern SP may be achieved by adjusting the content of metals included in the sacrificial pattern SP. As an example, the etch rate of the sacrificial pattern SP with respect to the first etchant EC1 (refer to FIG. 8G) and the second etchant EC2 (refer to FIG. 8H) may be achieved by adjusting the content of tin relative to total metal elements included in the sacrificial pattern SP.

The metal oxide included in the sacrificial pattern SP may include an amorphous structure. The amorphous metal oxide may refer to a type of oxide material that lacks a crystalline structure, meaning its atoms are arranged in a disordered manner. However, the present disclosure should not be limited thereto or thereby, and the sacrificial pattern SP may include metal oxide with a mixture of amorphous and crystalline structures. According to an embodiment, the sacrificial pattern may include amorphous zinc indium tin oxide (a-ZITO).

The crystallinity of the metal oxide included in sacrificial pattern SP may be confirmed through an X-ray diffraction (“XRD”) analysis. As an example, the crystallinity of the metal oxide included in the sacrificial pattern SP may be obtained from an area under crystalline peak relative to an area under all peaks including both of the area under crystalline peak and an area under amorphous peak using the X-ray diffraction (XRD) analysis. In this case, the area under crystalline peak may be obtained from a total area of peaks showing crystalline phase in the X-ray diffraction (XRD) pattern. In addition, the area under amorphous peak may mean an area of halo pattern in the X-ray diffraction (XRD) pattern. When the metal oxide included in the sacrificial pattern SP has the amorphous structure, peaks representing crystal planes may not be detected in the X-ray diffraction (XRD) pattern. That is, a sharp peak corresponding to a specific 20 value may not appear in the X-ray diffraction (XRD) pattern. In addition, when the metal oxide has an amorphous structure, the halo pattern corresponding to a broad and gentle peak may be observed in the X-ray diffraction (XRD) pattern.

FIG. 6 is a cross-sectional view schematically illustrating a method of evaluating an etch rate of a cover layer according to embodiment examples and comparative examples of the present disclosure.

Referring to FIGS. 5 and 6, the etch rate of the sacrificial pattern SP with respect to the first etchant EC1 and the etch rate of the sacrificial pattern SP with respect to the second etchant EC2 may vary depending on the composition and/or content of elements included in the sacrificial pattern SP. A test substrate TS may be used as shown in FIG. 6 to evaluate the etch rate of the sacrificial pattern SP with respect to each of the first etchant EC1 and the second etchant EC2.

Referring to FIGS. 5 and 6, the test substrate TS may include a glass substrate GLS, electrodes ELT, and the cover layer CVL. The electrodes ELT may be formed on the glass substrate GLS. The electrodes ELT may be formed of a material reactive to the first etchant EC1. The electrodes ELT may include molybdenum (Mo), and the electrodes ELT including molybdenum (Mo) may react to the first etchant EC1. The cover layer CVL may be formed on the glass substrate GLS to cover the electrodes ELT. The composition and/or content of elements included in the cover layer CVL are set different in embodiment examples and comparative examples.

The cover layer CVL according to first, second, and third embodiment examples includes indium zinc tin oxide (“IZTO”). A tin content relative to total metal elements of the cover layer CVL according to the first embodiment example is about 18 at %. A tin content relative to total metal elements of the cover layer CVL according to the second embodiment example is about 22 at %. A tin content relative to total metal elements of the cover layer CVL according to the third embodiment example is about 23 at %. A ratio of indium to zinc in the cover layer CVL according to the first, second, and third embodiment examples is about 1:1.

The cover layer CVL according to a first comparative example may include indium zinc oxide (“IZO”). The cover layer CVL according to a second comparative example may include indium gallium zinc oxide (“IGZO”).

The cover layer CVL according to each of the first, second, and third embodiment examples and each of the first and second comparative examples has a thickness t of about 250 angstroms (Å).

In the test substrate TS, the cover layer CVL that covers the electrodes ELT may correspond to the sacrificial pattern SP of the present disclosure, and the electrodes ELT covered by the cover layer CVL may correspond to the anodes AE of the present disclosure.

In evaluating the etch rate of the cover layer CVL with respect to the first etchant EC1, the etch rate of the cover layer CVL with respect to the first etchant EC1, that is, the third etch rate, and whether the electrodes ELT are exposed are determined. The first etchant EC1 may include orthophosphoric acid, acetic acid, nitric acid. In evaluating the etch rate of the cover layer CVL with respect to the first etchant EC1, the cover layer CVL is required to not be etched or to be etched to a lesser extent by the first etchant EC1 so as not to expose the electrodes ELT in order to protect the electrodes ELT from the first etchant EC1. That is, the cover layer CVL is required to have a low etch rate for the first etchant EC1, and this is determined by whether the electrodes ELT are exposed or not.

In evaluating the etch rate of the cover layer CVL with respect to the second etchant EC2, the etch rate of the cover layer CVL with respect to the second etchant EC2, that is, the fourth etch rate, and whether the electrodes ELT are exposed are determined. The second etchant EC2 may include water, nitric acid, and sulfuric acid. In evaluating the etch rate of the cover layer CVL with respect to the second etchant EC2, so that the cover layer CVL is required to be sufficiently etched to form the opening, i.e., the sacrificial opening OP-S through which the electrodes ELT are exposed, through the cover layer CVL. That is, the cover layer CVL is required to have a sufficient etch rate for the second etchant EC2, and this is determined by whether the electrodes ELT are exposed or not.

In Table 1 below, results derived from the etching evaluation for the first etchant EC1 and results derived from the etching evaluation for the second etchant EC2 in each of the cover layers CVL according to the first, second, and third embodiment examples and the first and second comparative examples are described.

TABLE 1

| | | First etchant | | Second etchant | |
|---|---|---|---|---|---|
| | | Etch | | Etch | |
| | Composition | rate | Exposure | rate | Exposure |
| | (content) | (Å/sec) | evaluation | (Å/sec) | evaluation |
| First | IZO | 31 | 0 | 34 | 0 |
| comparative | | | | | |
| example | | | | | |
| Second | IGZO | 130 | 0 | 51 | 0 |
| comparative | | | | | |
| example | | | | | |
| First | ZITO | 0.2 | X | 27 | 0 |
| embodiment | (Sn: 18 at %) | | | | |
| example | | | | | |
| Second | ZITO | 0 | X | 10 | 0 |
| embodiment | (Sn: 22 at %) | | | | |
| example | | | | | |
| Third | ZITO | 0 | X | 8 | 0 |
| embodiment | (Sn: 23 at %) | | | | |
| example | | | | | |

Referring to Table 1, the cover layer CVL according to the first and second comparative examples has a relatively high etch rate with respect to the first etchant EC1. Accordingly, the electrodes ELT are exposed without being covered by the cover layer CVL according to the first and second comparative examples. That is, when the sacrificial pattern SP includes IZO or IGZO, the sacrificial pattern SP has the high etch rate with respect to the first etchant EC1, and thus, the anodes AE are exposed and damaged in the wet etching process to form the barrier wall PW.

On the other hand, the cover layer CVL according to the first, second, and third embodiment examples has a relatively low etch rate with respect to the first etchant EC1. The cover layer CVL according to the first, second, and third embodiment examples has the etch rate smaller than about 0.5 angstroms per second (Å/sec) with respect to the first etchant EC1. Particularly, the cover layer CVL according to the second and third embodiment examples is not etched by the first etchant EC1. Accordingly, the electrodes ELT are covered by the cover layer CVL according to the first, second, and third embodiment examples and are not exposed. That is, when the sacrificial pattern SP includes ZITO, the sacrificial pattern SP has the low etch rate with respect to the first etchant EC1, and thus, the anodes AE are not exposed in the wet etching process to form the barrier wall PW and are protected. In particular, when the tin content relative to total metal elements in ZITO included in the sacrificial pattern SP is within a range from about 18 at % to about 23 at % and the ratio of indium to zinc is about 1:1, the sacrificial pattern SP has the etch rate that is sufficiently low with respect to the first etchant EC1, and thus, it is observed that the anodes AE disposed under the sacrificial pattern SP are protected.

In addition, referring to Table 1, it is observed that the electrodes ELT are exposed without being covered by the cover layer CVL according to the first, second, and third embodiment examples in the etching evaluation for the second etchant EC2. That is, when the sacrificial pattern SP includes ZITO, the sacrificial pattern SP has the sufficient etch rate with respect to the second etchant EC2, and thus, the sacrificial opening OP-S may be formed through the sacrificial pattern SP in the wet etching process to form the sacrificial opening OP-S. It is observed that the cover layer CVL according to the first, second, and third embodiment examples has the etch rate greater than about 5 Å/sec with respect to the second etchant EC2.

In the etching evaluation for the second etchant EC2, it is observed that the electrodes ELT are exposed without being covered by the cover layer CVL according to the first and second comparative examples. Each of an IZO thin film and an IGZO thin film has a sufficient etch rate with respect to the second etchant EC2. That is, each of the IZO thin film and the IGZO thin film may be etched by the second etchant EC2. Even though the second etchant EC2 applied to the cover layer CVL according to the first and second comparative examples is applied to the cover layer CVL according to the first, second, and third embodiment examples, it is observed that the cover layer CVL according to the first, second, and third embodiment examples is sufficiently etched.

In particular, when the tin content relative to total metal elements in ZITO included in the sacrificial pattern SP is within the range from about 18 at % to about 23 at % and the ratio of indium to zinc is about 1:1, the sacrificial pattern SP has the sufficient etch rate with respect to the second etchant EC2, and thus, it is observed that the opening is formed through the sacrificial pattern SP to expose the anodes AE disposed under the sacrificial pattern SP.

Referring to FIG. 5 again, the display panel DP may further include a capping pattern CP. The capping pattern CP may be disposed in the barrier wall opening OP-P and may be disposed on the cathode CE. The capping pattern CP may be patterned by the tip portion formed in the barrier wall PW.

FIG. 5 shows a structure in which the capping pattern CP is not in contact with the second inner side surface S2-P of the second barrier wall layer L2 as a representative example, however, the present disclosure should not be limited thereto or thereby. According to an embodiment, the capping pattern CP may be formed to be in contact with the second inner side surface S2-P of the second barrier wall layer L2. Meanwhile, according to an embodiment, the capping pattern CP may be omitted.

The dummy patterns DMP may be disposed on the barrier wall PW. The dummy patterns DMP may include a first layer dummy pattern D1, a second layer dummy pattern D2, and a third layer dummy pattern D3. The first, second, and third dummy patterns D1, D2, and D3 may be sequentially stacked on the upper surface of the second barrier wall layer L2 of the barrier wall PW in the third direction DR3.

The first layer dummy pattern D1 may include an organic material. As an example, the first layer dummy pattern D1 may include the same material as the material of the light emitting pattern EP. The first layer dummy pattern D1 may be substantially simultaneously formed with the light emitting pattern EP through a single process and may be separated from the light emitting pattern EP due to the undercut shape of the barrier wall PW.

The second layer dummy pattern D2 may include a conductive material. As an example, the second layer dummy pattern D2 may include the same material as the material of the cathode CE. The second layer dummy pattern D2 may be substantially simultaneously formed with the cathode CE through a single process and may be separated from the cathode CE due to the undercut shape of the barrier wall PW.

The third layer dummy pattern D3 may include the same material as the material of the capping pattern CP. The third layer dummy pattern D3 may be substantially simultaneously formed with the capping pattern CP through a single process and may be separated from the capping pattern CP due to the undercut shape of the barrier wall PW.

A dummy opening OP-D may be defined through the dummy patterns DMP. The dummy opening OP-D may correspond to the light emitting opening OP-E. The dummy opening OP-D may include an area (hereinafter, referred to as a first dummy area) defined by an inner side surface of the first layer dummy pattern D1, an area (hereinafter, referred to as a second dummy area) defined by an inner side surface of the second layer dummy pattern D2, and an area (hereinafter, referred to as a third dummy area) defined by an inner side surface of the third layer dummy pattern D3. When viewed in the plane, each of the first, second, and third layer dummy patterns D1, D2, and D3 may have a closed-line shape surrounding the light emitting area PXA.

FIG. 5 shows a structure in which the inner side surfaces of the first, second, and third layer dummy patterns D1, D2, and D3 are aligned with the second inner side surface S2-P of the second barrier wall layer L2 as a representative example, however, the present disclosure should not be limited thereto or thereby. According to an embodiment, the first, second, and third layer dummy patterns D1, D2, and D3 may cover the second inner side surface S2-P of the second barrier wall layer L2.

The thin film encapsulation layer TFE may be disposed on the display element layer DP-OL. The thin film encapsulation layer TFE may include a lower encapsulation inorganic pattern LIL, an encapsulation organic layer OL, and an upper encapsulation inorganic layer UIL.

The lower encapsulation inorganic pattern LIL may be disposed to overlap the light emitting opening OP-E in a plan view. The lower encapsulation inorganic pattern LIL may cover the light emitting element ED and the dummy patterns DMP, and a portion of the lower encapsulation inorganic pattern LIL may be disposed inside the barrier wall opening OP-P. According to an embodiment, the lower encapsulation inorganic pattern LIL may be in contact with each of the first inner side surface S1-P of the first barrier wall layer L1 and the second inner side surface S2-P of the second barrier wall layer L2.

The encapsulation organic layer OL may cover the lower encapsulation inorganic pattern LIL and may provide a flat upper surface thereon. The upper encapsulation inorganic layer UIL may be disposed on the encapsulation organic layer OL.

The lower encapsulation inorganic pattern LIL and the upper encapsulation inorganic layer UIL may protect the display element layer DP-OL from moisture and oxygen, and the encapsulation organic layer OL may protect the display element layer DP-OL from a foreign substance such as dust particles.

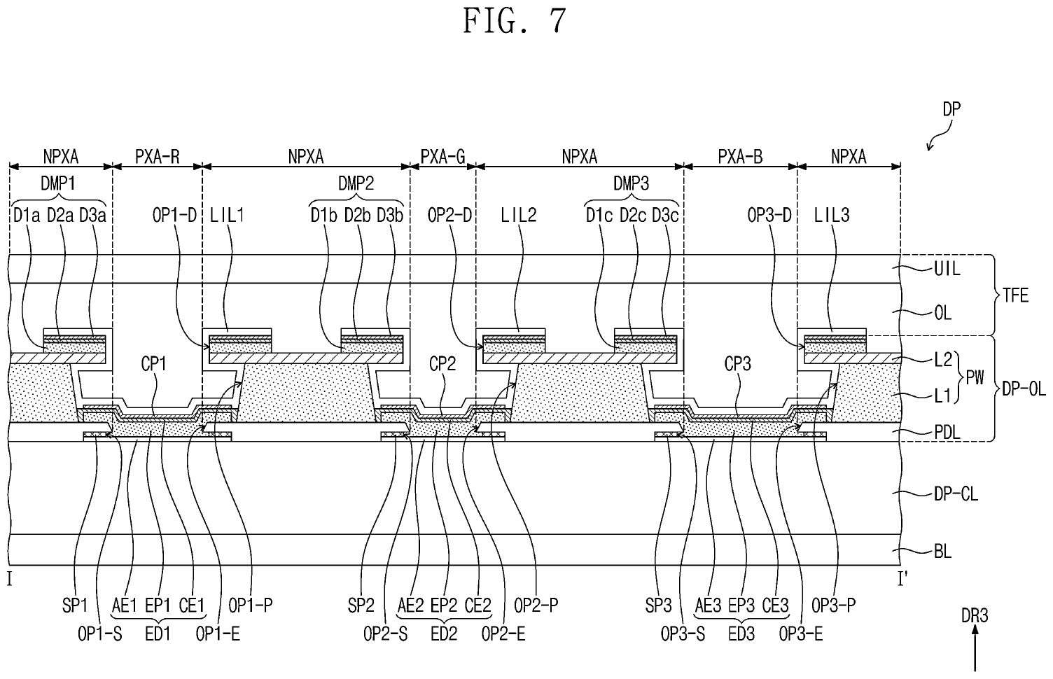

FIG. 7 is a cross-sectional view of the display panel DP according to an embodiment of the present disclosure. FIG. 7 is a cross-sectional view of the display panel DP taken along a line I-I′ of FIG. 4. FIG. 7 is an enlarged cross-sectional view of one first light emitting area PXA-R, one second light emitting area PXA-G, and one third light emitting area PXA-B, and the above-descriptions on the light emitting area PXA of FIG. 5 may be equally applied to the first, second, and third light emitting areas PXA-R, PXA-G, and PXA-B.

Referring to FIG. 7, the display panel DP may include the base layer BL, the circuit element layer DP-CL, the display element layer DP-OL, and the thin film encapsulation layer TFE. The display element layer DP-OL may include the light emitting elements ED1, ED2, and ED3, sacrificial patterns SP1, SP2, and SP3, the pixel definition layer PDL, the barrier wall PW, and dummy patterns DMP1, DMP2, and DMP3.

The light emitting elements ED1, ED2, and ED3 may include the first light emitting element ED1, the second light emitting element ED2, and the third light emitting element ED3. The first light emitting element ED1 may include a first anode AE 1, a first light emitting pattern EP1, and a first cathode CE1. The second light emitting element ED2 may include a second anode AE2, a second light emitting pattern EP2, and a second cathode CE2. The third light emitting element ED3 may include a third anode AE3, a third light emitting pattern EP3, and a third cathode CE3. The first, second, and third anodes AE1, AE2, and AE3 may be provided in plural patterns. The first light emitting pattern EP1 may provide the red light, the second light emitting pattern EP2 may provide the green light, and the third light emitting pattern EP3 may provide the blue light.

First, second, and third light emitting openings OP1-E, OP2-E, and OP3-E may be defined through the pixel definition layer PDL. The first light emitting opening OP1-E may expose at least a portion of the first anode AE1. The first light emitting area PXA-R may be defined as an area of an upper surface of the first anode AE1, which is exposed through the first light emitting opening OP1-E. The second light emitting opening OP2-E may expose at least a portion of the second anode AE2. The second light emitting area PXA-G may be defined as an area of an upper surface of the second anode AE2, which is exposed through the second light emitting opening OP2-E. The third light emitting opening OP3-E may expose at least a portion of the third anode AE3. The third light emitting area PXA-B may be defined as an area of an upper surface of the third anode AE3, which is exposed through the third light emitting opening OP3-E.

The sacrificial patterns SP1, SP2, and SP3 may include a first sacrificial pattern SP1, a second sacrificial pattern SP2, and a third sacrificial pattern SP3. The first, second, and third sacrificial patterns SP1, SP2, and SP3 may be disposed on the upper surfaces of the first, second, and third anodes AE1, AE2, and AE3, respectively. First, second, and third sacrificial openings OP1-S, OP2-S, and OP3-S may be defined through the first, second, and third sacrificial patterns SP1, SP2, and SP3 to correspond to the first, second, and third light emitting openings OP1-E, OP2-E, and OP3-E, respectively.

In the present embodiment, first, second, and third barrier wall openings OP1-P, OP2-P, and OP3-P may be defined through the barrier wall PW to correspond to the first, second, and third light emitting openings OP1-E, OP2-E, and OP3-E, respectively.

Each of the first, second, and third barrier wall openings OP1-P, OP2-P, and OP3-P may include the first opening area A1 (refer to FIG. 8G) and the second opening area A2 (refer to FIG. 8G). The first barrier wall layer L1 may include the first inner side surfaces S1-P (refer to FIG. 5) that define the first opening areas A1 of the first, second, and third barrier wall openings OP1-P, OP2-P, and OP3-P, and the second barrier wall layer L2 may include the second inner side surfaces S2-P (refer to FIG. 5) that define the second opening areas A2 of the first, second, and third barrier wall openings OP1-P, OP2-P, and OP3-P.

The first light emitting pattern EP1 and the first cathode CE1 may be disposed in the first barrier wall opening OP1-P, the second light emitting pattern EP2 and the second cathode CE2 may be disposed in the second barrier wall opening OP2-P, and the third light emitting pattern EP3 and the third cathode CE3 may be disposed in the third barrier wall opening OP3-P. The first, second, and third cathodes CE1, CE2, and CE3 may be in contact with the first inner side surfaces S1-P (refer to FIG. 5) of the first barrier wall layer L1, respectively.

In the present embodiment, the first, second, and third cathodes CE1, CE2, and CE3 may be physically separated from each other by the second barrier wall layer L2 forming the tip portion, may be formed in the light emitting openings OP1-E, OP2-E, and OP3-E, respectively, and may be in contact with the first barrier wall layer L1. Accordingly, the first, second, and third cathodes CE1, CE2, and CE3 may be electrically connected to each other and may receive a common voltage. As the first barrier wall layer L1 that is in contact with the first, second, and third cathodes CE1, CE2, and CE3 has a relatively high electrical conductivity compared with the second barrier wall layer L2, a contact resistance between the first barrier wall layer L1 and the first, second, and third cathodes CE1, CE2, and CE3 may be reduced. Thus, a common cathode voltage may be provided evenly to the light emitting areas PXA-R, PXA-G, and PXA-B.

According to the present disclosure, the first, second, and third light emitting patterns EP1, EP2, and EP3 may be deposited after being patterned in the unit of pixel by the tip portion defined in the barrier wall PW. That is, the first, second, and third light emitting patterns EP1, EP2, and EP3 may be commonly formed using an open mask but may be easily divided into plural portions in the unit of pixel by the barrier wall PW.

On the other hand, in a case where the light emitting patterns EP1, EP2, and EP3 are patterned using a fine metal mask (“FMM”), a support spacer protruding from the conductive barrier wall is required to support the fine metal mask. In addition, since the fine metal mask is spaced apart from a base surface on which a patterning process is performed by a height of the barrier wall and the support spacer, there may be limitations to implementing a high resolution of the display device. In addition, as the fine metal mask is in contact with the support spacer, foreign substances may remain on the support spacer, or the support spacer may be damaged by getting scratches due to the fine metal mask after the patterning process of the light emitting patterns EP1, EP2, and EP3. Accordingly, defects may occur in the display panel.

According to the present embodiment, as the display panel DP includes the barrier wall PW, the light emitting elements ED1, ED2, and ED3 may be physically and easily separated from each other. Accordingly, a current leakage or a driving error between the light emitting areas PXA-R, PXA-G, and PXA-B adjacent to each other may be prevented, and each of the light emitting elements ED1, ED2, and ED3 may be driven independently.

In particular, since the light emitting patterns EP1, EP2, and EP3 are patterned without masks that are in contact with components in the display area DA (refer to FIG. 1B), a defective rate of the display panel DP may be reduced, and a process reliability of the display panel DP may be improved. As the light emitting patterns are patterned without the support spacer protruding from the barrier wall PW, the size of the light emitting areas PXA-R, PXA-G, and PXA-B may be reduced, and the high resolution of the display panel DP may be implemented.

In addition, when manufacturing a large-sized display panel DP, a process cost may be reduced by omitting a production of a large-sized mask, and the display panel DP with improved process reliability may be provided because the display panel DP is not affected by defects that may occur in the large-sized mask.

Capping patterns CP1, CP2, and CP3 may include a first capping pattern CP1, a second capping pattern CP2, and a third capping pattern CP3. The first, second, and third capping patterns CP1, CP2, and CP3 may be disposed on the first, second, and third cathodes CE1, CE2, and CE3, respectively, and may be disposed in the first, second, and third barrier wall openings OP1-P, OP2-P, and OP3-P, respectively.

The dummy patterns DMP1, DMP2, and DMP3 may include a plurality of first dummy patterns DMP1, a plurality of second dummy patterns DMP2, and a plurality of third dummy patterns DMP3. The first dummy patterns DMP1, the second dummy patterns DMP2, and the third dummy patterns DMP3 may include first layer dummy patterns D1a, D1b, and D1c, respectively, may include second layer dummy patterns D2a, D2b, and D2c, respectively, and may include third layer dummy patterns D3a, D3b, and D3c, respectively.

The first dummy patterns DMP1 may include first-first, second-first, and third-first layer dummy patterns D1a, D2a, and D3a that surround the first light emitting area PXA-R when viewed in the plane. The first-first layer dummy pattern D1a may include the same material as the first light emitting pattern EP1 and may be formed through the same process as the first light emitting pattern EP1. The second-first layer dummy pattern D2a may include the same material as the first cathode CE1 and may be formed through the same process as the first cathode CE1. The third-first layer dummy pattern D3a may include the same material as the first capping pattern CP1 and may be formed through the same process as the first capping pattern CP1.

The second dummy patterns DMP2 may include first-second, second-second, and third-second layer dummy patterns D1b, D2b, and D3b that surround the second light emitting area PXA-G when viewed in the plane. The first-second layer dummy pattern D1b may include the same material as the second light emitting pattern EP2 and may be formed through the same process as the second light emitting pattern EP2. The second-second layer dummy pattern D2b may include the same material as the second cathode CE2 and may be formed through the same process as the second cathode CE2. The third-second layer dummy pattern D3b may include the same material as the second capping pattern CP2 and may be formed through the same process as the second capping pattern CP2.

The third dummy patterns DMP3 may include first-third, second-third, and third-third layer dummy patterns D1c, D2c, and D3c that surround the third light emitting area PXA-B when viewed in the plane. The first-third layer dummy pattern D1c may include the same material as the third light emitting pattern EP3 and may be formed through the same process as the third light emitting pattern EP3. The second-third layer dummy pattern D2c may include the same material as the third cathode CE3 and may be formed through the same process as the third cathode CE3. The third-third layer dummy pattern D3c may include the same material as the third capping pattern CP3 and may be formed through the same process as the third capping pattern CP3.

First, second, and third dummy openings OP1-D, OP2-D, and OP3-D corresponding to the first, second, and third light emitting openings OP1-E, OP2-E, and OP3-E, respectively, may be defined through the dummy patterns DMP1, DMP2, and DMP3. The first dummy opening OP1-D may be defined by inner side surfaces of the first-first, second-first, and third-first layer dummy patterns D1a, D2a, and D3a, the second dummy opening OP2-D may be defined by inner side surfaces of the first-second, second-second, and third-second layer dummy patterns D1b, D2b, and D3b, and the third dummy opening OP3-D may be defined by inner side surfaces of the first-third, second-third, and third-third layer dummy patterns D1c, D2c, and D3c.

The thin film encapsulation layer TFE may include lower encapsulation inorganic patterns LIL1, LIL2, and LIL3, the encapsulation organic layer OL, and the upper encapsulation inorganic layer UIL. In the present embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The first, second, and third lower encapsulation inorganic patterns LIL1, LIL2, and LIL3 may correspond to the first, second, and third light emitting openings OP1-E, OP2-E, and OP3-E, respectively.

The first lower encapsulation inorganic pattern LIL1 may cover the first light emitting element ED1 and the first-first, second-first, and third-first layer dummy patterns D1a, D2a, and D3a, and a portion of the first lower encapsulation inorganic pattern LIL1 may be disposed in the first barrier wall opening OP1-P. The second lower encapsulation inorganic pattern LIL2 may cover the second light emitting element ED2 and the first-second, second-second, and third-second layer dummy patterns D1b, D2b, and D3b, and a portion of the second lower encapsulation inorganic pattern LIL2 may be disposed in the second barrier wall opening OP2-P. The third lower encapsulation inorganic pattern LIL3 may cover the third light emitting element ED3 and the first-third, second-third, and third-third layer dummy patterns D1c, D2c, and D3c, and a portion of the third lower encapsulation inorganic pattern LIL3 may be disposed in the third barrier wall opening OP3-P. The first, second, and third lower encapsulation inorganic patterns LIL1, LIL2, and LIL3 may be arranged spaced apart from each other in a pattern shape.

FIGS. 8A to 8K are cross-sectional views illustrating a method of manufacturing the display panel according to an embodiment of the present disclosure. In FIGS. 8A to 8K, the same/similar reference numerals denote the same/similar elements in FIGS. 1A to 7, and thus, detailed descriptions of the same/similar elements will be omitted.

The manufacturing method of the display panel may include: forming the anode on the base layer and the sacrificial pattern on the anode; forming the pixel definition layer provided with the light emitting opening to expose at least the portion of the sacrificial pattern on the base layer; forming a preliminary barrier wall on the pixel definition layer; etching the preliminary barrier wall to form the barrier wall through which the barrier wall opening overlapping the light emitting opening in a plan view is defined; etching the sacrificial pattern to form the sacrificial opening through which at least the portion of the anode is exposed; and forming the light emitting pattern and the cathode in the barrier wall opening. The cathode is in contact with the barrier wall. The sacrificial pattern includes the metal oxide containing tin, indium, and zinc, the tin content relative to the total content of tin, indium, and zinc contained in the sacrificial pattern is equal to or greater than about 18 at % and equal to or smaller than about 23 at %, and the ratio of indium to zinc included in the sacrificial pattern is about 1:1.

Referring to FIG. 8A, the manufacturing method of the display panel may include providing a preliminary display panel DP-I. In the present embodiment, the preliminary display panel DP-I may include the base layer BL and the circuit element layer DP-CL.

The circuit element layer DP-CL may be formed by a conventional circuit element manufacturing method that forms an insulating layer, a semiconductor layer, and a conductive layer by a coating or depositing process and patterns the insulating layer, the semiconductor layer, and the conductive layer by a photolithography process and an etching process to form the semiconductor pattern, the conductive pattern, and the signal line.

The manufacturing method of the display panel may include forming the anode AE on the preliminary display panel DP-I and forming the sacrificial pattern SP.

The anode AE may be formed on the circuit element layer DP-CL. The anode AE may be formed by forming a first conductive layer (hereinafter, referred to as a “preliminary anode layer”) using various methods, e.g., a deposition process, a sputtering process, etc., and selectively patterning the first conductive layer (or the preliminary anode layer) using a photolithography process and an etching process.

The sacrificial pattern SP may be formed on the anode AE. The sacrificial pattern SP may be formed by forming a second conductive layer (hereinafter, referred to as a “preliminary sacrificial pattern layer”) using various methods, e.g., a deposition process, a sputtering process, etc., and selectively patterning the second conductive layer (or the preliminary sacrificial pattern layer) using a photolithography process and an etching process. The sacrificial pattern SP may be disposed directly on the anode AE. A lower surface of the sacrificial pattern SP may be in contact with the upper surface of the anode AE.

According to an embodiment, the deposition process or the sputtering process to form the preliminary anode layer and the preliminary sacrificial pattern layer may be sequentially performed, and then the preliminary anode layer and the preliminary sacrificial pattern layer may be patterned together to form the anode AE and the sacrificial pattern SP.

Referring to FIG. 8B, the manufacturing method of the display panel may include a heat treatment process. The heat treatment process may be carried out at a temperature of about 250 to about 260 Celsius degrees for about 30 to about 60 minutes.

The metal oxide included in the anode AE may be crystallized after the heat-treatment process. On the other hand, the metal oxide of the sacrificial pattern SP may maintain the amorphous structure even though the heat treatment process is performed. That is, a crystallization degree of the metal oxide included in the anode AE may be greater than a crystallization degree of the metal oxide included in the sacrificial pattern SP in the heat treatment process. Accordingly, the etch selectivity of the sacrificial pattern SP having the amorphous structure may increase with respect to the anode AE having the crystalline structure in the subsequent etching process of the sacrificial pattern SP.

Referring to FIG. 8C, the manufacturing method of the display panel may include the forming of the pixel definition layer PDL. The pixel definition layer PDL may be disposed on the insulating layer, e.g., the fifth insulating layer 50 (refer to FIG. 5), that is disposed at the uppermost position among the insulating layers of the circuit element layer DP-CL.

The pixel definition layer PDL through which the light emitting opening OP-E is defined may be formed by forming an insulating layer (or a preliminary pixel definition layer) using various methods, e.g., a deposition process, and selectively patterning the insulating layer (or the preliminary pixel definition layer) using a photolithography process and an etching process. At least the portion of the sacrificial pattern SP may be exposed through the light emitting opening OP-E without being covered by the pixel definition layer PDL.

Referring to FIG. 8D, the manufacturing method of the display panel may include the forming of the preliminary barrier wall PW-I on the pixel definition layer PDL. The forming of the preliminary barrier wall PW-I may include forming a first preliminary barrier wall layer L1-I on the pixel definition layer PDL and forming a second preliminary barrier wall layer L2-I on the first preliminary barrier wall layer L1-I.

The forming of the first preliminary barrier wall layer L1-I may be carried out by a process of depositing the conductive material. In the present embodiment, the conductive material used to form the first preliminary barrier wall layer L1-I may include aluminum (Al). As an example, the conductive material used to form the first preliminary barrier wall layer L1-I may include the pure aluminum or the aluminum alloy. As an example, the aluminum alloy may include the small amount of nickel (Ni).

The forming of the second preliminary barrier wall layer L2-I may be carried out by a process of depositing the conductive material. A metal material used to form the second preliminary barrier wall layer L2-I may be different from a metal material used to form the first preliminary barrier wall layer L1-I. The metal material used to form the second preliminary barrier wall layer L2-I may be titanium (Ti), however, the present disclosure should not be limited thereto or thereby. According to an embodiment, materials for the second preliminary barrier wall layer L2-I should not be particularly limited as long as the materials have the etch selectivity with respect to the first preliminary barrier wall layer L1-I when exposed to the first etchant EC1 (refer to FIG. 8G).

Referring to FIGS. 8E to 8G, the manufacturing method of the display panel may include the etching of the preliminary barrier wall PW-I to form the barrier wall PW through which the barrier wall opening OP-P is defined. The forming of the barrier wall PW may include forming a first photoresist layer PR1 on the preliminary barrier wall PW-I and etching the first preliminary barrier wall layer L1-I and the second preliminary barrier wall layer L2-I.

Referring to FIG. 8E, the manufacturing method of the display panel may include forming the first photoresist layer PR1 on the preliminary barrier wall PW-I. The first photoresist layer PR1 may be formed by forming a preliminary photoresist layer on the preliminary barrier wall PW-I and patterning the preliminary photoresist layer using a photomask. A photo opening OP-PR corresponding to the anode AE may be formed through the first photoresist layer PR1 by the patterning process.

Referring to FIGS. 8F and 8G, the manufacturing method of the display panel may include etching the first preliminary barrier wall layer L1-I and the second preliminary barrier wall layer L2-I to form the barrier wall PW from the preliminary barrier wall PW-I. The etching of the preliminary barrier wall PW-I may be performed twice. The etching of the preliminary barrier wall PW-I may include a first etching process and a second etching process.

Referring to FIG. 8F, the first etching process of the preliminary barrier wall PW-I may include dry etching the first preliminary barrier wall layer L1-I and the second preliminary barrier wall layer L2-I using the first photoresist layer PR1 as a mask.

The first etching process may be performed in an etching environment where the first preliminary barrier wall layer L1-I and the second preliminary barrier wall layer L2-I have substantially the same etch selectivity. Accordingly, an inner side surface of the first preliminary barrier wall layer L1-I and an inner side surface of the second preliminary barrier wall layer L2-I, which define a preliminary barrier wall opening OP-PI, may be substantially aligned with each other.

Referring to FIG. 8G, after the first etching process of the first preliminary barrier wall layer L1-I and the second preliminary barrier wall layer L2-I, the second etching process of the first preliminary barrier wall layer L1-I may be performed. The second etching process of the first preliminary barrier wall layer L1-I may include wet etching the first preliminary barrier wall layer L1-I using the first photoresist layer PR1 as a mask to form the barrier wall opening OP-P. The second etching process of the first preliminary barrier wall layer L1-I may correspond to the wet etching process to form the barrier wall PW described above with reference to FIG. 5. In the present disclosure, the second etching process of the first preliminary barrier wall layer L1-I may be referred to as an undercut etching process.

In the second etching process of the first preliminary barrier wall layer L1-I, the first barrier wall layer L1 and the second barrier wall layer L2 may be formed. As the first preliminary barrier wall layer L1-I is selectively etched in the second etching process of the first preliminary barrier wall layer L1-I, the inner side surface of the barrier wall PW may have the undercut shape when viewed in the cross-section. Since the second barrier wall layer L2 protrudes in a direction toward the center of the anode AE compared with the first barrier wall layer L1, the tip portion TP may be formed in the barrier wall PW.

The barrier wall opening OP-P may include the first opening area A1 and the second opening area A2, which are sequentially defined in a thickness direction, i.e., the third direction DR3. The first barrier wall layer L1 may include the first inner side surface S1-P that defines a portion of the first opening area A1 of the barrier wall opening OP-P, and the second barrier wall layer L2 may include the second inner side surface S2-P that defines the second opening area A2.

In the present embodiment, the second etching process may be performed in an environment where the etch selectivity between the first preliminary barrier wall layer L1-I and the second preliminary barrier wall layer L2-I is high. Accordingly, the inner side surface of the barrier wall PW, which defines the barrier wall opening OP-P, may have the undercut shape when viewed in the cross-section. In detail, as the first etchant EC1 is provided in the second etching process and the etch rate of the first preliminary barrier wall layer L1-I with respect to the first etchant EC1 is greater than the etch rate of the second preliminary barrier wall layer L2-I with respect to the first etchant EC1, the degree of etching of the first preliminary barrier wall layer L1-I may be greater than the degree of etching of the second preliminary barrier wall layer L2-I. Accordingly, the first inner side surface S1-P of the first barrier wall layer L1 may be more recessed inwardly than the second inner side surface S2-P of the second barrier wall layer L2. The second opening area A2 may have the width smaller than the width of the first opening area A1. The tip portion TP may be formed in the barrier wall PW by the portion of the second barrier wall layer L2, which protrudes in the direction toward the center of the anode AE compared with the first barrier wall layer L1.

According to the present disclosure, the etch rate of the sacrificial pattern SP with respect to the first etchant EC1 may be low. The etch rate of the sacrificial pattern SP with respect to the first etchant EC1 may be smaller than about 0.5 Å/sec. Accordingly, the sacrificial pattern SP is etched less or not etched by the first etchant EC1 in the wet etching process to form the barrier wall PW, and thus, the anode AE disposed under the sacrificial pattern SP may not be exposed. That is, during the wet etching process to form the barrier wall PW, the anode AE may be covered by the sacrificial pattern SP and may be prevented from being damaged due to chemical solutions.

In the present embodiment, even though an additional thin film that protects the sacrificial pattern SP is not formed, the anode AE may be prevented from being damaged in the wet etching process to form the barrier wall PW. That is, according to the present embodiment, the anode AE may be prevented from being damaged in the wet etching process to form the barrier wall PW even though an additional deposition process and/or an additional patterning process is not performed.

Referring to FIG. 8H, the process of forming the sacrificial opening OP-S through the sacrificial pattern SP may be performed. The etching process of the sacrificial pattern SP to form the sacrificial opening OP-S may be carried out by a wet etching method, and the sacrificial pattern SP may be etched using the first photoresist layer PR1 and a portion of the barrier wall PW, i.e., the second barrier wall layer L2, as a mask.

When a portion of the sacrificial pattern SP is removed by the wet etching process, the sacrificial opening OP-S may be formed (or defined) through the sacrificial pattern. The sacrificial opening OP-S may penetrate the sacrificial pattern SP, and the portion of the upper surface of the anode AE may be exposed.

During the etching process of the sacrificial pattern SP, the second etchant EC2 different from the first etchant EC1 (refer to FIG. 8G) may be provided. The sacrificial pattern SP may be etched by the second etchant EC2. The sacrificial pattern SP may have a predetermined etch rate with respect to the second etchant EC2. The sacrificial pattern SP may have the etch rate greater than about 5 Å/sec with respect to the second etchant EC2.

The etching process of the sacrificial pattern SP may be performed in an environment where the etch selectivity between the sacrificial pattern SP and the anode AE is high, and thus, the anode AE may be prevented from being etched with the sacrificial pattern SP. In detail, as the sacrificial pattern SP having the etch rate greater than the etch rate of the anode AE with respect to the second etchant EC2 is disposed between the pixel definition layer PDL and the anode AE, the anode AE may be prevented from being exposed through the sacrificial opening OP-S during the etching process and thus may be prevented from being etched and damaged.

The sacrificial pattern SP and the anode AE may have different crystallization degrees at a first temperature. The sacrificial pattern SP may have a first crystallization degree at the first temperature, and the anode AE may have a second crystallization degree greater than the first crystallization degree at the first temperature. As an example, the sacrificial pattern SP may have the amorphous structure at the first temperature, and the anode AE may have the crystalline structure at the first temperature. In the present disclosure, the first temperature may be about 250° C. The crystallization degree may be obtained by the following Equation 2:

$$crystallization degree = {P}_{1} / ( {P}_{1} + {P}_{2} ) \qquad Equation 2$$

In Equation 2, P₁ denotes a total sum of areas under crystalline peak in the X-ray diffraction (XRD) pattern, and P₂ denotes a total sum of areas under amorphous peak in the X-ray diffraction (XRD) pattern.

In the heat treatment process described with reference to FIG. 8B, the metal oxide included in the sacrificial pattern SP may have the amorphous structure, and the metal oxide included in the anode AE may have the crystalline structure. Accordingly, the etch selectivity of the sacrificial pattern SP with respect to the anode AE may increase in the etching process of the sacrificial pattern SP to form the sacrificial opening OP-S.

At least a portion of the sacrificial opening OP-S may overlap the light emitting opening OP-E in a plan view. The sacrificial opening OP-S may have a width greater than a width of the light emitting opening OP-E, however, the present disclosure should not be limited thereto or thereby. According to an embodiment, the width of the sacrificial opening OP-S may be substantially the same as the width of the light emitting opening OP-E, and the width of the sacrificial opening OP-S may be smaller than the width of the light emitting opening OP-E. At least the portion of the anode AE may be exposed through the sacrificial opening OP-S and the light emitting opening OP-E without being covered by the sacrificial pattern SP and the pixel definition layer PDL.

The etching process of the sacrificial pattern SP may be performed in an environment where the etch selectivity between the sacrificial pattern SP and the first and second barrier wall layers L1 and L2 of the barrier wall PW is high, and thus, the first and second barrier wall layers L1 and L2 may be prevented from being etched together with the sacrificial pattern SP.

Referring to FIG. 8I, the manufacturing method of the display panel may include forming the light emitting pattern EP, forming the cathode CE, and forming the capping pattern CP after removing the first photoresist layer PR1.

Each of the forming of the light emitting pattern EP, the forming of the cathode CE, and the forming of the capping pattern CP may be performed by a deposition process. The forming of the light emitting pattern EP may be performed by a thermal evaporation process, the forming of the cathode CE may be performed by a chemical vapor deposition (“CVD”) process, and the forming of the capping pattern CP may be performed by a thermal evaporation process, however, the present disclosure should not be limited thereto or thereby.

In the forming of the light emitting pattern EP, the light emitting pattern EP may be separated by the tip portion TP formed in the barrier wall PW and may be disposed in the light emitting opening OP-E and the barrier wall opening OP-P. In the forming of the light emitting pattern EP, a first layer preliminary dummy pattern D1-I may be formed on the barrier wall PW to be spaced apart from the light emitting pattern EP. The light emitting pattern EP may be formed on the anode AE.

In the forming of the cathode CE, the cathode CE may be separated by the tip portion TP formed in the barrier wall PW and may be disposed in the barrier wall opening OP-P. The cathode CE may be provided with a high angle of incidence relative to the light emitting pattern EP, and the cathode CE may be formed to contact the first inner side surface S1-P of the first barrier wall layer L1. In the forming of the cathode CE, a second layer preliminary dummy pattern D2-I may be formed on the barrier wall PW to be spaced apart from the cathode CE. The anode AE, the light emitting pattern EP, and the cathode CE may form the light emitting element ED.

In the forming of the capping pattern CP, the capping pattern CP may be separated by the tip portion TP formed in the barrier wall PW and may be disposed in the barrier wall opening OP-P. In the forming of the capping pattern CP, a third layer preliminary dummy pattern D3-I may be formed on the barrier wall PW to be spaced apart from the capping pattern CP. Meanwhile, according to an embodiment, the forming of the capping pattern CP may be omitted.

The first, second, and third layer preliminary dummy patterns D1-I, D2-I, and D3-I may form a preliminary dummy pattern DMP-I, and the preliminary dummy pattern DMP-I may be provided with the dummy opening OP-D defined therethrough. The dummy opening OP-D may include a first opening area, a second opening area, and a third opening area, which are sequentially arranged in the thickness direction, i.e., the third direction DR3. The first opening area of the dummy opening OP-D may be defined by an inner side surface of the first layer preliminary dummy pattern D1-I, the second opening area of the dummy opening OP-D may be defined by an inner side surface of the second layer preliminary dummy pattern D2-I, and the third opening area of the dummy opening OP-D may be defined by an inner side surface of the third layer preliminary dummy pattern D3-I.

Then, the manufacturing method of the display panel may include forming a preliminary lower encapsulation inorganic pattern LIL-I. The preliminary lower encapsulation inorganic pattern LIL-I may be formed by a deposition process. According to an embodiment, the preliminary lower encapsulation inorganic pattern LIL-I may be formed by a chemical vapor deposition (CVD) process. The preliminary lower encapsulation inorganic pattern LIL-I may be formed on the barrier wall PW and the cathode CE, and a portion of the preliminary lower encapsulation inorganic pattern LIL-I may be formed inside the barrier wall opening OP-P.

Referring to FIGS. 81 and 8J, the manufacturing method of the display panel may include forming a second photoresist layer PR2, patterning the preliminary lower encapsulation inorganic pattern LIL-I to form the lower encapsulation inorganic pattern LIL, and patterning the preliminary dummy patterns DMP-I to form the dummy patterns DMP.

The second photoresist layer PR2 may be formed by forming a preliminary photoresist layer and pattering the preliminary photoresist layer using a photomask. The second photoresist layer PR2 may be patterned by a patterning process to have a pattern corresponding to the light emitting opening OP-E.

According to the patterning of the preliminary lower encapsulation inorganic pattern LIL-I, the preliminary lower encapsulation inorganic pattern LIL-I may be dry-etched, and thus, portions of the preliminary lower encapsulation inorganic pattern LIL-I, which overlap the other anodes, may be removed except a portion of the preliminary lower encapsulation inorganic pattern LIL-I, which overlaps a corresponding anode AE in a plan view. As an example, when the preliminary lower encapsulation inorganic pattern LIL-I corresponds to the first anode AE1 (refer to FIG. 7), the portions of the preliminary lower encapsulation inorganic pattern LIL-I, which correspond to the second and third anodes AE2 and AE3 (refer to FIG. 7), may be removed.

The lower encapsulation inorganic pattern LIL overlapping the corresponding light emitting opening OP-E in a plan view may be formed from the patterned preliminary lower encapsulation inorganic pattern LIL-I. A portion of the lower encapsulation inorganic pattern LIL may be disposed in the barrier wall opening OP-P to cover the light emitting element ED, and the other portion of the lower encapsulation inorganic pattern LIL may be disposed on the barrier wall PW.

According to the patterning of the preliminary dummy patterns DMP-I, the first, second, and third layer preliminary dummy patterns D1-I, D2-I, and D3-I may be dry-etched, and thus, portions of the first, second, and third layer preliminary dummy patterns D1-I, D2-I, and D3-I, which correspond to the other anodes, may be removed except a portion of the first, second, and third layer preliminary dummy patterns D1-I, D2-I, and D3-I, which overlaps a corresponding anode AE in a plan view. As an example, when the first, second, and third layer preliminary dummy patterns D1-I, D2-I, and D3-I correspond to the first anode AE1 (refer to FIG. 7), the portions of the first, second, and third layer preliminary dummy patterns D1-I, D2-I, and D3-I, which overlap the second and third anodes AE2 and AE3 (refer to FIG. 6) in a plan view, may be removed.

The first, second, and third layer dummy patterns D1, D2, and D3 may be formed from the patterned first, second, and third layer preliminary dummy patterns D1-I, D2-I, and D3-I, and thus, the dummy patterns DMP including the first, second, and third layer dummy patterns D1, D2, and D3 may be formed. The first, second, and third layer dummy patterns D1, D2, and D3 may have a closed-line shape surrounding the corresponding light emitting area PXA (refer to FIG. 5) when viewed in the plane.

Referring to FIG. 8K, the manufacturing method of the display panel may include forming the encapsulation organic layer OL and the upper encapsulation inorganic layer UIL to complete the display panel DP after removing of the second photoresist layer PR2 (refer to FIG. 8J). The encapsulation organic layer OL may be formed by coating an organic material with an inkjet method, however, the present disclosure should not be limited thereto or thereby. The encapsulation organic layer OL may provide a flat upper surface thereon. Then, the upper encapsulation inorganic layer UIL may be formed by depositing an inorganic material. Accordingly, the display panel DP including the base layer BL, the circuit element layer DP-CL, the display element layer DP-OL, and the thin film encapsulation layer TFE may be formed.

Forming the light emitting elements providing another color in the barrier wall PW and the pixel definition layer PDL and forming the lower encapsulation inorganic pattern covering the light emitting elements providing another color may be further performed between the forming of the lower encapsulation inorganic pattern LIL and the completing of the display panel DP. Accordingly, as shown in FIG. 7, the display panel DP including the first, second, and third light emitting elements ED1, ED2, and ED3, the first, second, and third capping patterns CP1, CP2, and CP3, the first-first, first-second, and first-third layer dummy patterns D1a, D2a, and D3a, the second-first, second-second, and second-third layer dummy patterns D1b, D2b, and D2c, the third-first, third-second, and third-third layer dummy patterns D1c, D2c, and D3c, and the first, second, and third lower encapsulation inorganic patterns LIL1, LIL2, and LIL3 may be formed.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. A display panel comprising:
a base layer;
an anode disposed on the base layer;
a sacrificial pattern disposed on the anode and provided with a sacrificial opening to expose a portion of an upper surface of the anode;
a pixel definition layer disposed on the base layer to cover at least a portion of the sacrificial pattern and provided with a light emitting opening overlapping the sacrificial opening;
a barrier wall disposed on the pixel definition layer and provided with a barrier wall opening overlapping the light emitting opening;
a light emitting pattern disposed on the anode and disposed in the barrier wall opening; and
a cathode disposed on the light emitting pattern and being in contact with the barrier wall,
wherein the sacrificial pattern comprises a metal oxide comprising tin (Sn), indium (In), and zinc (Zn), a tin content relative to a total content of tin, indium, and zinc contained in the sacrificial pattern is equal to or greater than about 18 atomic percent (at %) and equal to or smaller than about 23 at %, and a ratio of indium to zinc contained in the sacrificial pattern is about 1:1.

2. The display panel of claim 1, wherein the barrier wall comprises:
a first barrier wall layer disposed on the pixel definition layer; and
a second barrier wall layer disposed on the first barrier wall layer, and
wherein the barrier wall opening comprises:
a first opening area defined by an inner side surface of the first barrier wall layer; and
a second opening area defined by an inner side surface of the second barrier wall layer and having a width smaller than a width of the first opening area.

3. The display panel of claim 2, wherein an etch rate of the sacrificial pattern with respect to a first etchant is smaller than an etch rate of the first barrier wall layer with respect to the first etchant.

4. The display panel of claim 3, wherein the etch rate of the sacrificial pattern with respect to the first etchant is smaller than about 0.5 angstroms per second (Å/sec).

5. The display panel of claim 3, wherein the etch rate of the first barrier wall layer with respect to the first etchant is greater than an etch rate of the second barrier wall layer with respect to the first etchant.

6. The display panel of claim 3, wherein the first barrier wall layer comprises aluminum (Al) or an aluminum alloy.

7. The display panel of claim 3, wherein an etch rate of the sacrificial pattern with respect to a second etchant different from the first etchant is greater than about 5 Å/sec.

8. The display panel of claim 1, wherein the metal oxide included in the sacrificial pattern has an amorphous structure.

9. The display panel of claim 1, wherein the anode comprises silver.

10. The display panel of claim 1, wherein the anode comprises:
a first layer disposed on the base layer and comprising indium tin oxide (ITO);
a second layer disposed on the first layer and comprising silver; and
a third layer disposed on the second layer and comprising indium tin oxide (ITO), and
wherein a crystallization degree of the indium tin oxide included in the third layer is greater than a crystallization degree of the metal oxide included in the sacrificial pattern.

11. A method of manufacturing a display panel, comprising:
forming an anode on a base layer and a sacrificial pattern on the anode;
forming a pixel definition layer provided with a light emitting opening to expose at least a portion of the sacrificial pattern on the base layer;
forming a preliminary barrier wall on the pixel definition layer;
etching the preliminary barrier wall to form a barrier wall through which a barrier wall opening overlapping the light emitting opening is defined;
etching the sacrificial pattern to form a sacrificial opening through which at least a portion of the anode is exposed; and
forming a light emitting pattern and a cathode in the barrier wall opening,
wherein the cathode is in contact with the barrier wall,
wherein the sacrificial pattern comprises a metal oxide comprising tin, indium, and zinc, a tin content relative to a total content of tin, indium, and zinc contained in the sacrificial pattern is equal to or greater than about 18 at % and equal to or smaller than about 23 at %, and a ratio of indium to zinc included in the sacrificial pattern is about 1:1.

12. The method of claim 11, wherein the forming of the preliminary barrier wall comprises:
forming a first preliminary barrier wall layer on the pixel definition layer; and
forming a second preliminary barrier wall layer on the first preliminary barrier wall layer, and
wherein the etching of the preliminary barrier wall comprises:
first etching the preliminary barrier wall to form a preliminary barrier wall opening; and
second etching the preliminary barrier wall to form the barrier wall to comprise a first barrier wall layer and a second barrier wall layer disposed on the first barrier wall layer.

13. The method of claim 12, wherein the first etching of the preliminary barrier wall comprises dry etching the first and second preliminary barrier wall layers, and
the second etching of the preliminary barrier wall comprises wet etching the first preliminary barrier wall layer.

14. The method of claim 12, wherein a first etchant is provided in the second etching of the preliminary barrier wall, and an etch rate of the sacrificial pattern with respect to the first etchant is smaller than an etch rate of the first barrier wall layer with respect to the first etchant.

15. The method of claim 14, wherein the etch rate of the sacrificial pattern with respect to the first etchant is smaller than about 0.5 Å/sec.

16. The method of claim 11, wherein a second etchant is provided in the etching of the sacrificial pattern, and an etch rate of the sacrificial pattern with respect to the second etchant is greater than about 5 Å/sec.

17. The method of claim 16, wherein the etch rate of the sacrificial pattern with respect to the second etchant is greater than an etch rate of the anode with respect to the second etchant.

18. The method of claim 11, further comprising heat treating the anode and the sacrificial pattern after the forming of the anode and the sacrificial pattern and before the forming of the pixel definition layer,
wherein a crystallization degree of a metal oxide included in the anode is greater than a crystallization degree of the metal oxide included in the sacrificial pattern in the heat treating.

19. The method of claim 18, wherein the heat treating is carried out at a temperature of about 250 to about 260 Celsius degrees for about 30 to about 60 minutes.

20. The method of claim 11, wherein the forming of the anode and the sacrificial pattern comprises:
forming a preliminary anode layer on the base layer;
forming a preliminary sacrificial pattern layer on the preliminary anode layer; and
patterning the preliminary anode layer and the preliminary sacrificial pattern layer to form the anode and the sacrificial pattern, respectively.
